(19) United States
(12) Patent Application Publication
(10) Pub. No.: US 2024/0072029 A1
(43) Pub. Date: Feb. 29, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Tzuan-Horng Liu, Taoyuan City (TW); Hao-Yi Tsai, Hsinchu City (TW)

(73) Assignee: Taiwan Semiconductor Manufacturing Company, Ltd., Hsinchu (TW)

(21) Appl. No.: 17/894,095

(22) Filed: Aug. 23, 2022

(51) Int. Cl. H01L 25/18; H01L 23/00; H01L 23/31; H01L 23/538; H01L 25/00

(52) U.S. Cl. CPC H01L 25/18; H01L 23/3128; H01L 23/5383; H01L 23/5385; H01L 23/5389; H01L 24/13; H01L 24/16; H01L 24/32; H01L 24/73; H01L 25/50; H01L 2224/13147; H01L 2224/13582; H01L 2224/13655; H01L 2224/16227; H01L 2224/32225; H01L 2224/73204

(57) ABSTRACT

A semiconductor package includes a first redistribution structure, a second redistribution structure, a first die, a first encapsulant, a second die, a second encapsulant, conductive connectors, and a third die. The second redistribution structure is over the first redistribution structure. The first die is located between the first redistribution structure and the second redistribution structure. The first encapsulant laterally encapsulates the first die. The second die is disposed on and electrically connected to the second redistribution structure. The second encapsulant laterally encapsulates the second die. The conductive connectors surround the second die and are embedded in the second encapsulant. The third die is disposed over the second die. The third die is in physical contact with the second encapsulant and the conductive connectors.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more of the smaller components to be integrated into a given area. These smaller electronic components also require smaller packages that utilize less area than previous packages. Some smaller types of packages for semiconductor components include quad flat packages (QFP), pin grid array (PGA) packages, ball grid array (BGA) packages, flip chips (FC), three-dimensional integrated circuits (3DICs), wafer level packages (WLPs), package-on-package (PoP) structures, and integrated fan-out (InFO) packages, etc. Although existing semiconductor packages have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1K are schematic cross-sectional views illustrating various stages of a manufacturing method of a semiconductor package in accordance with some embodiments of the disclosure.

FIG. 2 is an enlarged cross-sectional view of the conductive connectors in FIG. 1G.

FIG. 3A to FIG. 3L are schematic cross-sectional views illustrating various stages of a manufacturing method of a semiconductor package in accordance with some alternative embodiments of the disclosure.

FIG. 4A to FIG. 4L are schematic cross-sectional views illustrating various stages of a manufacturing method of a semiconductor package in accordance with some alternative embodiments of the disclosure.

FIG. 5A to FIG. 5K are schematic cross-sectional views illustrating various stages of a manufacturing method of a semiconductor package in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

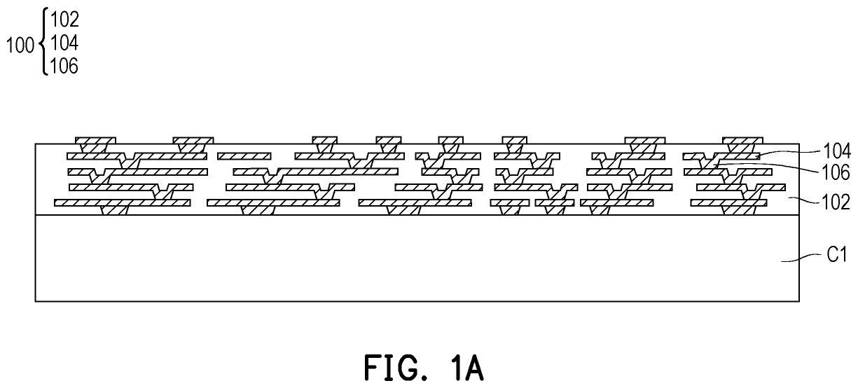

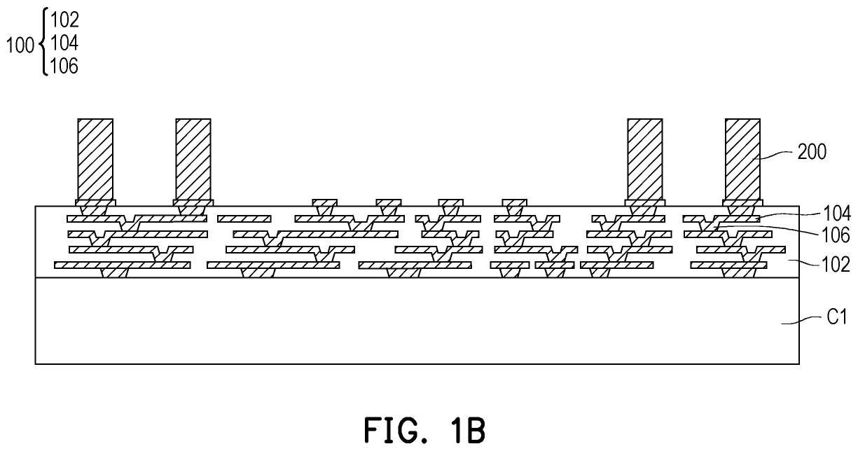

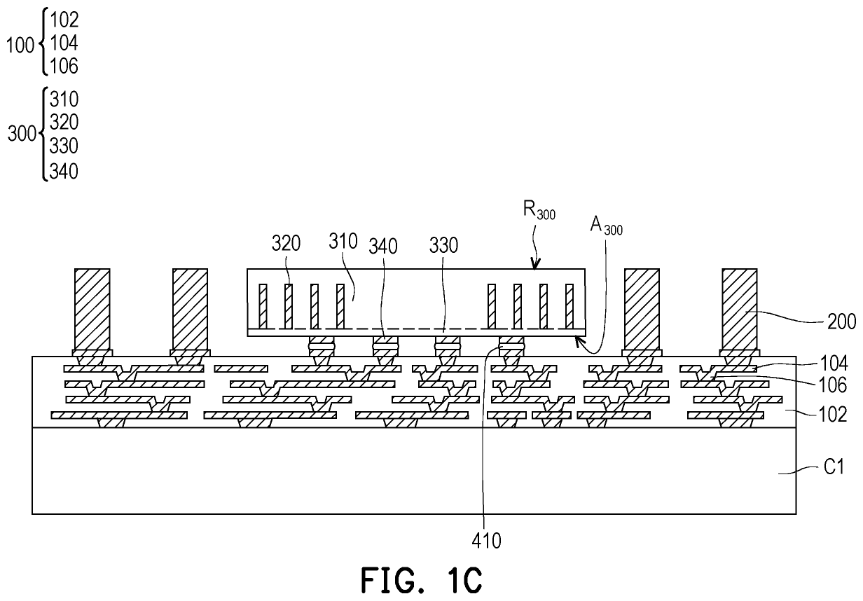

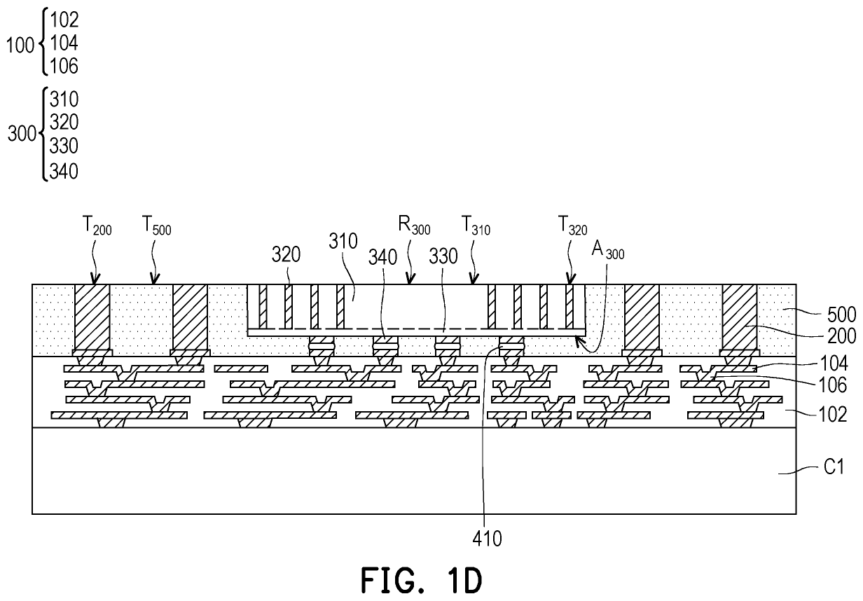

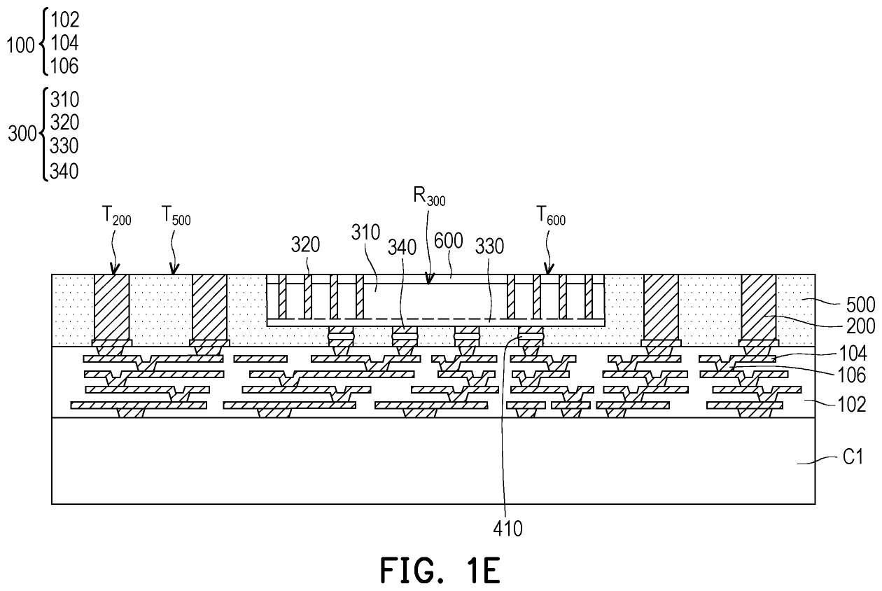

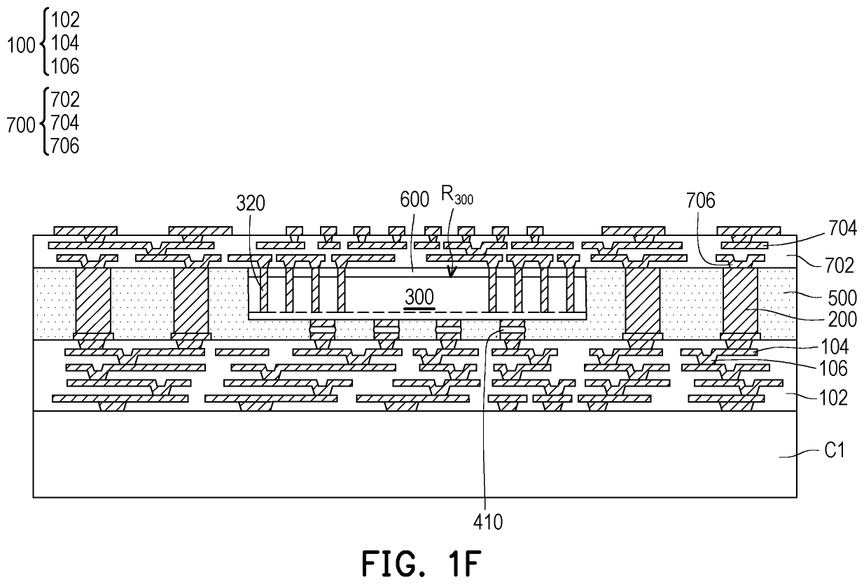

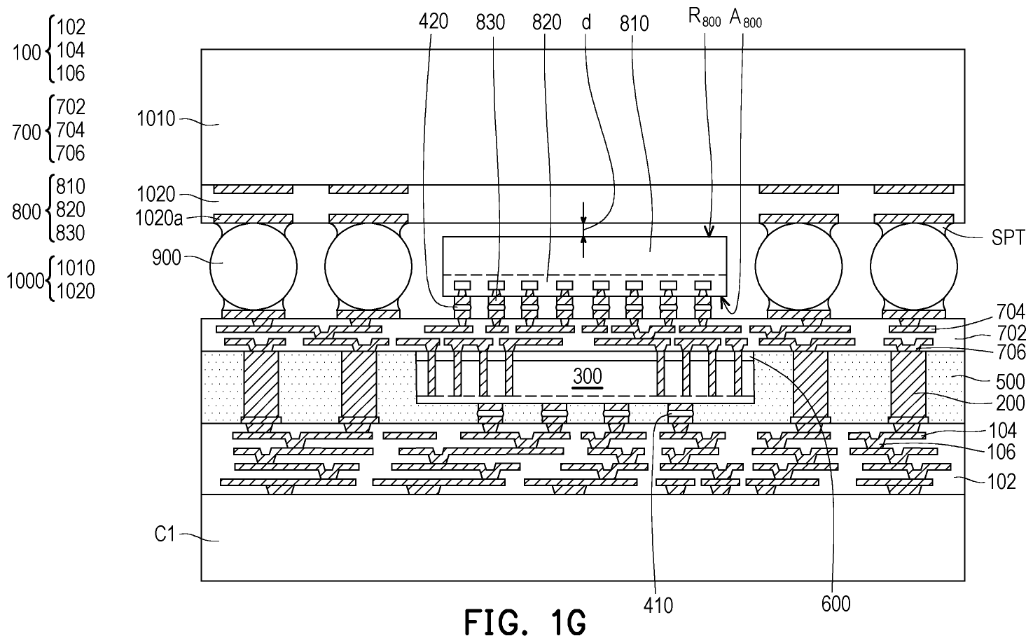

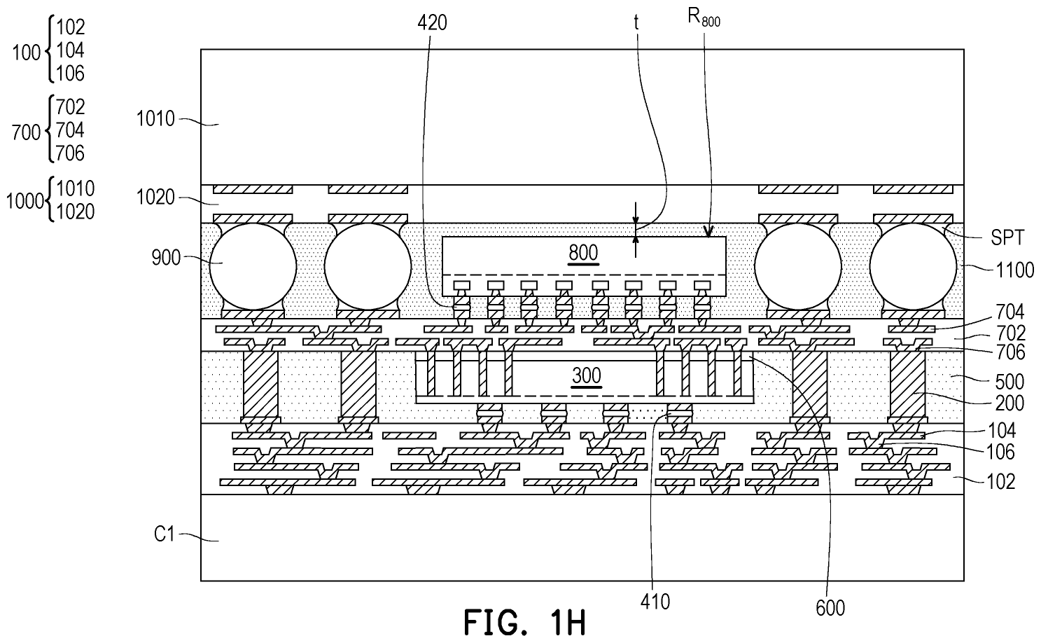

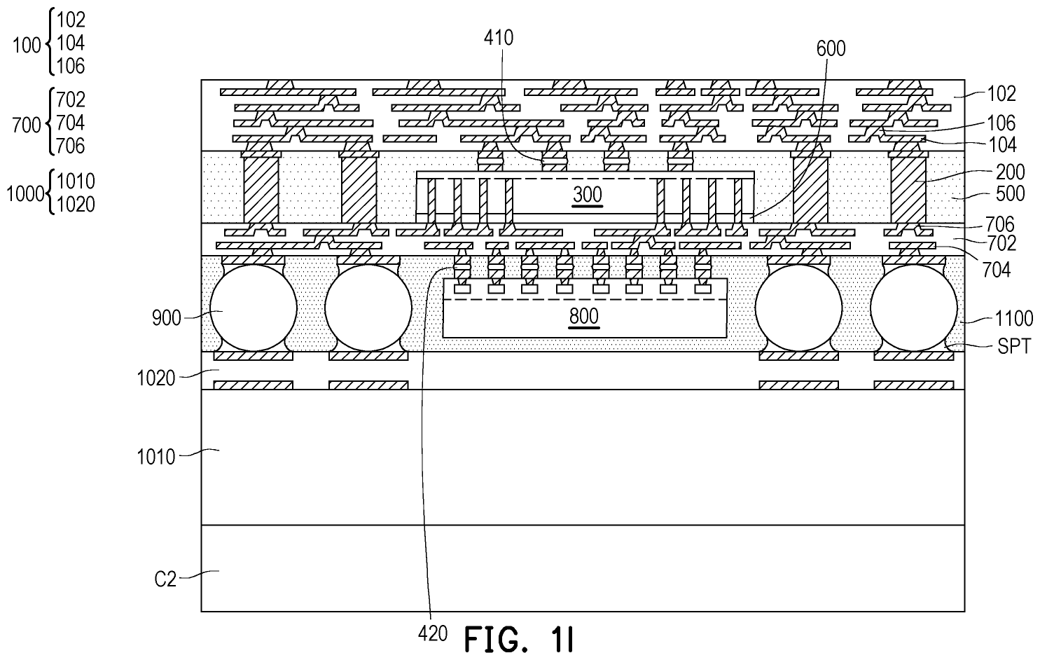

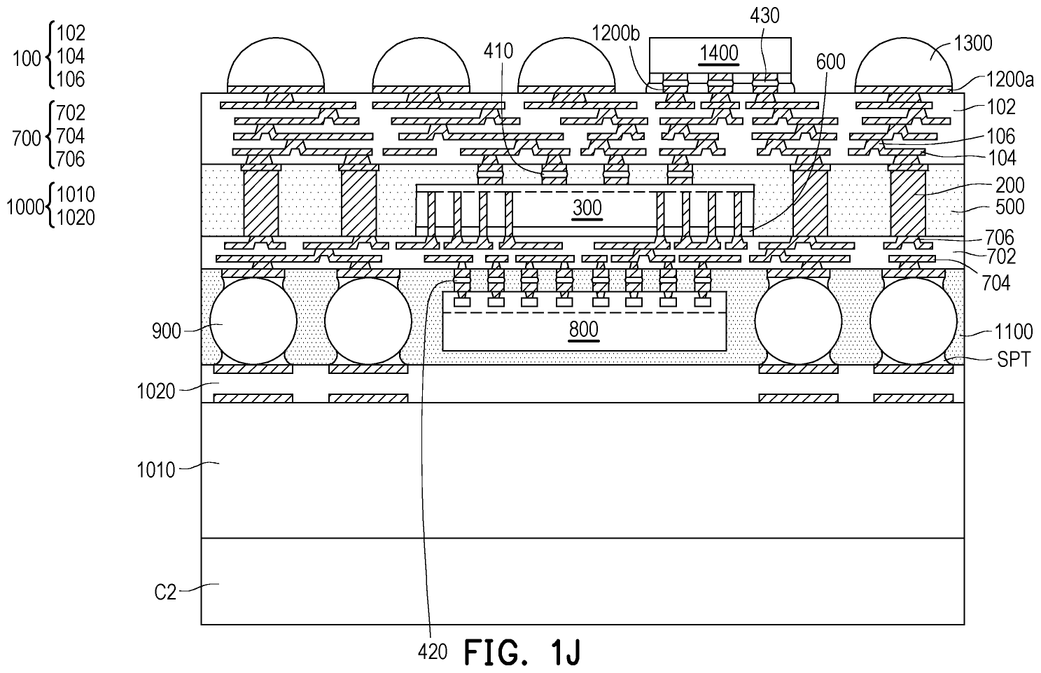

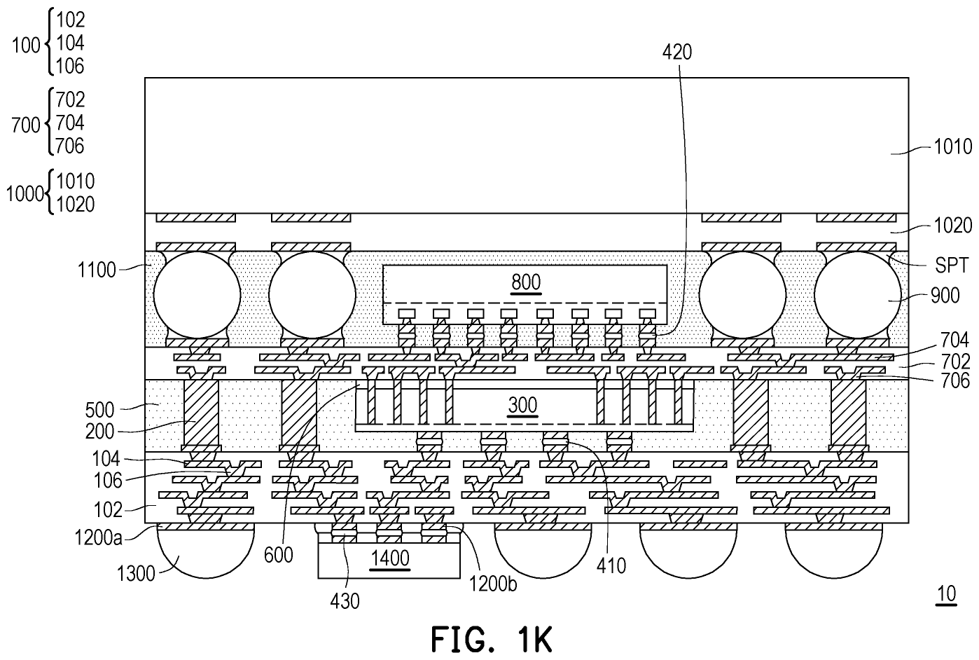

FIG. 1A to FIG. 1K are schematic cross-sectional views illustrating various stages of a manufacturing method of a semiconductor package 10 in accordance with some embodiments of the disclosure. Referring to FIG. 1A, a carrier C1 is provided. In some embodiments, the carrier C1 is made of silicon, polymer, polymer composite, metal foil, ceramic, glass, glass epoxy, tape, or other suitable material for structural support. Thereafter, a redistribution structure 100 is formed on the carrier C1. In some embodiments, an adhesive layer (not shown) is formed between the carrier C1 and the redistribution structure 100. The adhesive layer may be detached from the carrier C1 by, e.g., shining an ultra-violet (UV) light on the carrier C1 in a subsequent carrier de-bonding process. For example, the adhesive layer is a light-to-heat-conversion (LTHC) coating layer or the like.

As illustrated in FIG. 1A, the redistribution structure 100 includes a dielectric layer 102, a plurality of conductive patterns 104, and a plurality of conductive vias 106. In some embodiments, a material of the dielectric layer 102 includes polyimide, epoxy resin, acrylic resin, phenol resin, benzocyclobutene (BCB), polybenzooxazole (PBO), or any other suitable polymer-based dielectric material. Alternatively, the dielectric layer 102 may be formed of oxides or nitrides, such as silicon oxide, silicon nitride, aluminum oxide, hafnium oxide, hafnium zirconium oxide, or the like. In some embodiments, the dielectric layer 102 includes resin mixed with filler. The dielectric layer 102 may be formed by suitable fabrication techniques, such as spin-on coating, chemical vapor deposition (CVD), plasma-enhanced chemical vapor deposition (PECVD), or the like.

For simplicity, the dielectric layer 102 is illustrated as a bulky layer in FIG. 1A, but it should be understood that the dielectric layer 102 may be constituted by multiple dielectric layers. In some embodiments, the conductive vias 106 and some of the conductive patterns 104 are embedded in the dielectric layer 102. In some embodiments, the conductive patterns 104 located at different level heights are connected to one another through the conductive vias 106. In other words, the conductive patterns 104 are electrically connected to one another through the conductive vias 106. In some embodiments, a material of the conductive patterns 104 and the conductive vias 106 includes aluminum, titanium, copper, nickel, tungsten, or alloys thereof. The conductive patterns 104 and the conductive vias 106 may be formed by electroplating, deposition, and/or photolithography and etching. In some embodiments, the conductive patterns 104 and the conductive vias 106 are formed simultaneously. In some embodiments, the conductive patterns 104 transmit signals horizontally and the conductive vias 106 transmit signals vertically. As illustrated in FIG. 1A, the topmost conductive patterns 104 are disposed on top of the dielectric layer 102. For example, the topmost conductive patterns 104 are exposed. It should be noted that the number of the conductive patterns 104 and the number of the conductive vias 106 illustrated in FIG. 1A are merely for illustrative purposes, and the disclosure is not limited thereto. In some alternative embodiments, fewer or more layers of the conductive patterns 104 and/or the conductive vias 106 may be formed depending on the circuit design.

Referring to FIG. 1B, a plurality of conductive structures 200 is formed on the redistribution structure 100. For example, the conductive structures 200 are formed on some of the topmost conductive patterns 104 of the redistribution structure 100. In some embodiments, the conductive structures 200 are formed by the following steps. First, a seed layer (not shown) is conformally formed on the redistribution structure 100. In some embodiments, the seed layer includes a titanium/copper composite layer and is formed by a sputtering process. Then, a patterned photoresist layer (not shown) is formed on the seed layer. In some embodiments, the patterned photoresist layer has a plurality of openings that correspond to locations of the respective conductive structures 200 to be formed. Subsequently, the openings of the patterned photoresist layer are filled with a conductive material. In some embodiments, the conductive material includes copper, copper alloys, or the like. The conductive material is formed by electroplating, deposition, or the like. After the openings are filled with the conductive material, the patterned photoresist layer and the seed layer underneath the patterned photoresist layer are removed through an ashing or a stripping process, so as to obtain the conductive structures 200. In some embodiments, the conductive structures 200 include conductive pillars, conductive posts, conducive balls, or the like.

Referring to FIG. 1C, a die 300 is placed on the redistribution structure 100. In some embodiments, the die 300 includes a semiconductor substrate 310, a plurality of through semiconductor vias (TSV) 320, an interconnect structure 330, and a plurality of connectors 340. In some embodiments, the semiconductor substrate 310 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 310 may include active components (e.g., transistors or the like) and/or passive components (e.g., resistors, capacitors, inductors, or the like) formed therein. In some embodiments, the TSVs 320 are embedded in the semiconductor substrate 310. In some embodiments, a material of the TSVs 320 includes aluminum, titanium, copper, nickel, tungsten, or alloys thereof.

As illustrated in FIG. 1C, the interconnect structure 330 is disposed on the semiconductor substrate 310. In some embodiments, the interconnect structure 330 includes an inter-dielectric layer (not shown) and a plurality of conducive patterns (not shown) embedded in the inter-dielectric layer. In some embodiments, the conductive patterns of the interconnect structure 330 are electrically connected to the active components and/or the passive components embedded in the semiconductor substrate 310. In some embodiments, the connectors 340 are disposed on the interconnect structure 330 to electrically/physically connect the die 300 with other components. In some embodiments, a material of the connectors 340 includes cobalt, titanium, tungsten, copper, aluminum, tantalum, titanium nitride, tantalum nitride, gold, silver, another metal, a metal alloy, or combinations thereof.

In some embodiments, the die 300 is capable of performing logic functions. For example, the die 300 may be Central Process Unit (CPU) dies, Graphic Process Unit (GPU) dies, Field-Programmable Gate Array (FPGA), or the like.

In some embodiments, the die 300 has an active surface A₃₀₀ and a rear surface R₃₀₀ opposite to the active surface A₃₀₀. In some embodiments, the connectors 340 of the die 300 are located on the active surface A₃₀₀. In some embodiments, the dies 300 are placed on the redistribution structure 100 through a pick-and-place process. In some embodiments, the die 300 is attached to the redistribution structure 100 through flip-chip bonding. For example, the connectors 340 of the die 300 may be attached to some of the topmost conductive patterns 104 of the redistribution structure 100 such that the active surface A₃₀₀ of the die 300 faces the redistribution structure 100. Meanwhile, the rear surface R₃₀₀ of the die 300 faces upward. In some embodiments, the connectors 340 of the die 300 are attached to the conductive patterns 104 of the redistribution structure 100 through conductive joints 410. In some embodiments, the conductive joints 410 include solder joints or the like, so as to securely fix the die 300 on the redistribution structure 100 and to electrically connect the die 300 and the redistribution structure 100.

As illustrated in FIG. 1C, the conductive structures 200 are arranged in an array and surround the die 300. For example, the die 300 is located in a central region of the subsequently formed semiconductor package 10 while the conductive structures 200 are located in a peripheral region of the subsequently formed semiconductor package 10.

Referring to FIG. 1C and FIG. 1D, an encapsulant 500 is formed on the redistribution structure 100 to laterally encapsulate the conductive structures 200 and the die 300. That is, the conductive structures 200 and the die 300 are embedded in the encapsulant 500. In some embodiments, the encapsulant 500 is formed by the following steps. First, an encapsulation material (not shown) is formed on the redistribution structure 100 to encapsulate the conductive structures 200 and the die 300. In other words, the conductive structures 200 and the die 300 are not revealed and are well protected by the encapsulation material. In some embodiments, the encapsulation material is a molding compound, a molding underfill (MUF), a resin (such as epoxy), or the like. In some embodiments, the encapsulation material may further include fillers, but the inclusion of the fillers is optional. In some embodiments, the encapsulation material is formed by a molding process. For example, the encapsulation material may be formed by a compression molding process, an injection molding process, or the like. Thereafter, a portion of the encapsulation material, a portion of each conductive structure 200, and a portion of the semiconductor substrate 310 of the die 300 are removed until the TSVs 320 of the die 300 are revealed, so as to form the encapsulant 500. In some embodiments, the portion of the encapsulation material, the portion of each conductive structure 200, and the portion of the semiconductor substrate 310 may be removed through a grinding process. The grinding process includes, for example, a mechanical grinding process, a chemical mechanical polishing (CMP), or the like. After grinding, the die 300 has a thickness ranging from about 30 μm to about 90 μm. Meanwhile, the die 300 has a length ranging from about 2 mm to about 12 mm, and a width ranging from about 2 mm to about 12 mm.

As illustrated in FIG. 1D, top surfaces T₂₀₀ of the conductive structures 200, the rear surface 8300 of the die 300 (i.e. a top surface T₃₁₀ of the semiconductor substrate 310 and top surfaces T₃₂₀ of the TSVs 320), and a top surface T₅₀₀ of the encapsulant 500 are substantially coplanar. In some embodiments, the encapsulant 500 is in physical contact with sidewalls of the conductive structures 200 and sidewalls of the die 300. In addition, the encapsulant 500 is also in physical contact with the topmost conductive patterns 104 of the redistribution structure 100, the connectors 340 of the die 300, and the conductive joints 410.

Referring to FIG. 1D and FIG. 1E, a portion of the semiconductor substrate 310 of the die 300 is removed to form a recess, and a protection layer 600 is formed to fill up the recess. In some embodiments, the semiconductor substrate 310 is partially removed through an etching process. The etching process includes an isotropic etching process and/or an anisotropic etching process. For example, the semiconductor substrates 310 may be partially removed through a wet etching process, a drying etching process, or a combination thereof. In some embodiments, the protection layer 600 includes a molding compound, a MUF, or the like. Alternatively, the protection layer 600 may be made of a polymeric material, such as polyimide, epoxy resin, acrylic resin, phenol resin, BCB, PBO, or other suitable polymer-based dielectric materials. In some embodiments, the protection layer 600 includes fillers. Alternatively, the protection layer 600 may be free of fillers.

As illustrated in FIG. 1E, each TSV 320 protrudes from the rear surface 8300 of the die 300. Meanwhile, the protruding portion of each TSV 320 is laterally encapsulated by the protection layer 600. In some embodiments, a top surface T₆₀₀ of the protection layer 600, the top surfaces T₂₀₀ of the conductive structures 200, and the top surface T₅₀₀ of the encapsulant 500 are substantially coplanar.

Referring to FIG. 1F, a redistribution structure 700 is formed on the conductive structures 200, the die 300, and the encapsulant 500. As illustrated in FIG. 1F, the redistribution structure 700 includes a dielectric layer 702, a plurality of conductive patterns 704, and a plurality of conductive vias 706. In some embodiments, a material of the dielectric layer 702 includes polyimide, epoxy resin, acrylic resin, phenol resin, BCB, PBO, or any other suitable polymer-based dielectric material. Alternatively, the dielectric layer 702 may be formed of oxides or nitrides, such as silicon oxide, silicon nitride, aluminum oxide, hafnium oxide, hafnium zirconium oxide, or the like. In some embodiments, the dielectric layer 702 includes resin mixed with filler. The dielectric layer 702 may be formed by suitable fabrication techniques, such as spin-on coating, CVD, PECVD, or the like.

For simplicity, the dielectric layer 702 is illustrated as a bulky layer in FIG. 1F, but it should be understood that the dielectric layer 702 may be constituted by multiple dielectric layers. In some embodiments, the conductive vias 706 and some of the conductive patterns 704 are embedded in the dielectric layer 702. In some embodiments, the conductive patterns 704 located at different level heights are connected to one another through the conductive vias 706. In other words, the conductive patterns 704 are electrically connected to one another through the conductive vias 706. In some embodiments, a material of the conductive patterns 704 and the conductive vias 706 includes aluminum, titanium, copper, nickel, tungsten, or alloys thereof. The conductive patterns 704 and the conductive vias 706 may be formed by electroplating, deposition, and/or photolithography and etching. In some embodiments, the conductive patterns 704 and the conductive vias 706 are formed simultaneously. In some embodiments, the conductive patterns 704 transmit signals horizontally and the conductive vias 706 transmit signals vertically. As illustrated in FIG. 1F, the topmost conductive patterns 704 are disposed on top of the dielectric layer 702. For example, the topmost conductive patterns 704 are exposed. It should be noted that the number of the conductive patterns 704 and the number of the conductive vias 706 illustrated in FIG. 1F are merely for illustrative purposes, and the disclosure is not limited thereto. In some alternative embodiments, fewer or more layers of the conductive patterns 704 and/or the conductive vias 706 may be formed depending on the circuit design.

As illustrated in FIG. 1F, the redistribution structure 700 is disposed over the redistribution structure 100 and over the rear surface 8300 of the die 300. In some embodiments, the redistribution structure 700 is in physical contact with the conductive structures 200, the die 300, the encapsulant 500, and the protection layer 600. For example, the bottommost conductive vias 706 of the redistribution structure 700 are in physical contact with the conductive structures 200 and the TSVs 320 of the die 300. On the other hand, the dielectric layer 702 is in physical contact with the encapsulant 500 and the protection layer 600. In some embodiments, the redistribution structure 700 is electrically connected to the conductive structures 200 and the die 300. For example, the conductive patterns 704 and the conductive vias 706 of the redistribution structure 700 are electrically connected to the conductive structures 200 and the die 300. As illustrated in FIG. 1F, the conductive structures 200 and the die 300 are located between the redistribution structure 100 and the redistribution structure 700. For example, the conductive structures 200 penetrate through the encapsulant 500 to electrically connect the redistribution structure 100 and the redistribution structure 700.

Referring to FIG. 1G, a die 800 is placed on the redistribution structure 700. In some embodiments, the die 800 includes a semiconductor substrate 810, an interconnect structure 820, and a plurality of connectors 830. In some embodiments, the semiconductor substrate 810 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 810 may include active components (e.g., transistors or the like) and/or passive components (e.g., resistors, capacitors, inductors, or the like) formed therein.

As illustrated in FIG. 1G, the interconnect structure 820 is disposed on the semiconductor substrate 810. In some embodiments, the interconnect structure 820 includes an inter-dielectric layer (not shown) and a plurality of conducive patterns (not shown) embedded in the inter-dielectric layer. In some embodiments, the conductive patterns of the interconnect structure 820 are electrically connected to the active components and/or the passive components embedded in the semiconductor substrate 810. In some embodiments, the connectors 830 are disposed on the interconnect structure 820 to electrically/physically connect the die 800 with other components. In some embodiments, a material of the connectors 830 includes cobalt, titanium, tungsten, copper, aluminum, tantalum, titanium nitride, tantalum nitride, gold, silver, another metal, a metal alloy, or combinations thereof. In some embodiments, the die 800 is capable of performing logic functions. For example, the die 800 may be CPU dies, GPU dies, FPGA, or the like.

In some embodiments, the die 800 has an active surface A₈₀₀ and a rear surface R₈₀₀ opposite to the active surface A₈₀₀. In some embodiments, the connectors 830 of the die 800 are located on the active surface A₈₀₀. In some embodiments, the die 800 is placed on the redistribution structure 700 through a pick-and-place process. In some embodiments, the die 800 is attached to the redistribution structure 700 through flip-chip bonding. For example, the connectors 830 of the die 800 may be attached to some of the topmost conductive patterns 704 of the redistribution structure 700 such that the active surface A₈₀₀ of the die 800 faces the redistribution structure 700. Meanwhile, the rear surface R₈₀₀ of the die 800 faces upward. In some embodiments, the connectors 830 of the die 800 are attached to the conductive patterns 704 of the redistribution structure 700 through conductive joints 420. In some embodiments, the conductive joints 420 include solder joints or the like, so as to securely fix the die 800 on the redistribution structure 700 and to electrically connect the die 800 and the redistribution structure 700. In some embodiments, a thickness of the die 800 ranges from about 100 μm to about 350 μm, a length of the die 800 ranges from about 2 mm to about 10 mm, and a width of the die 800 range from about 2 mm to about 10 mm.

After the die 800 is placed on the redistribution structure 700, a die 1000 is provided over the die 800 and the redistribution structure 700. For example, the die 1000 is provided such that the die 800 is located between the redistribution structure 700 and the die 1000. In some embodiments, the die 1000 is provided to be spatially separated from the die 800. For example, a distance d between the die 1000 and the rear surface 8800 of the die 800 ranges from about 10 μm to about 100 μm. In some embodiments, the die 1000 includes a semiconductor substrate 1010 and an interconnect structure 1020. In some embodiments, the semiconductor substrate 1010 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 1010 may include active components (e.g., transistors or the like) and/or passive components (e.g., resistors, capacitors, inductors, or the like) formed therein. As illustrated in FIG. 1G, the interconnect structure 1020 is disposed on the semiconductor substrate 1010. In some embodiments, the interconnect structure 1020 includes an inter-dielectric layer and a plurality of conducive patterns 1020a embedded in the inter-dielectric layer. In some embodiments, the conductive patterns 1020a of the interconnect structure 1020 are electrically connected to the active components and/or the passive components embedded in the semiconductor substrate 1010.

In some embodiments, the die 1000 is capable of performing storage functions. For example, the die 1000 may be Dynamic Random Access Memory (DRAM), Resistive Random Access Memory (RRAM), Static Random Access Memory (SRAM). Examples of the DRAM include High Bandwidth Memory (HBM), Wide I/O (WIO) Memory, Low-Power Double Date Rate (LPDDR) DRAM, or the like. In some embodiments, a thickness of the die 1000 ranges from about 500 μm to about 900 μm, a length of the die 800 ranges from about 10 mm to about 16 mm, and a width of the die 800 range from about 10 mm to about 16 mm.

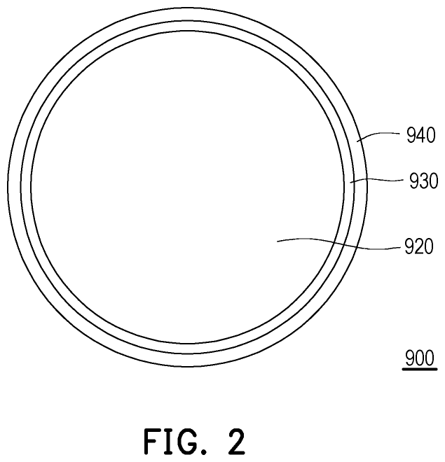

As illustrated in FIG. 1G, the die 1000 is attached to the redistribution structure 700 through a plurality of conductive connectors 900. In some embodiments, the conductive connectors 900 are in physical contact with the bottommost conductive patterns 1020a of the interconnect structure 1100 of the die 1000 and some of the topmost conductive patterns 704 of the redistribution structure 700. That is, the conductive connectors 900 are electrically connected to the die 1000 and the redistribution structure 700. In other words, the conductive connectors 900 electrically connect the redistribution structure 700 and the die 1000. In some embodiments, a solder paste SPT is presented between the conductive connectors 900 and the bottommost conductive patterns 1020a of the die 1000 and between the conductive connectors 900 and some of the topmost conductive patterns 704 of the redistribution structure 700 to further strengthen the bonding between these elements. As illustrated in FIG. 1G, the conductive connectors 900 are conductive balls. The detailed structure of each conductive connector 900 (i.e. the conductive ball) will be described in detail below in conjunction with FIG. 2.

FIG. 2 is an enlarged cross-sectional view of the conductive connectors 900 in FIG. 1G. Referring to FIG. 2, the conductive connector 900 is a composite conductive ball. For example, the conductive connector 900 is a tri-layered conductive ball. In some embodiments, the conductive connector 900 includes a copper ball 920, a nickel layer 930, and a solder layer 940. In some embodiments, the copper ball 920 is referred to as a copper core. The nickel layer 930 is coated on the copper ball 920. In other words, the nickel layer 930 wraps around the copper ball 920. Meanwhile, the solder layer 940 is coated on the nickel layer 930. That is, the solder layer 940 wraps around the nickel layer 930. In some embodiments, a diameter of the copper ball 920 ranges from about 180 μm to about 220 μm. On the other hand, a thickness of the nickel layer 930 ranges from about 2 μm to about 4 μm. Moreover, a thickness of the solder layer 940 ranges from about 8 μm to about 28 μm.

Referring back to FIG. 1G, in some embodiments, one end of each of the conductive balls is in physical contact with the redistribution structure 700, and another end of each of the conductive balls is in physical contact with the die 1000. In other words, the conductive connectors 900 (i.e. the conductive balls) are located between the redistribution structure 700 and the die 1000. In some embodiments, the conductive connectors 900 are arrange in an array and surround the die 800. For example, the die 800 is located in a central region of the subsequently formed semiconductor package 10 while the conductive connectors 900 are located in a peripheral region of the subsequently formed semiconductor package 10. As illustrated in FIG. 1G, each of the conductive connectors 900 has a curvy sidewall. In some embodiments, a diameter of each conductive connector 900 ranges from about 150 μm to about 300 μm.

In some embodiments, the conductive connectors 900 are formed on the conductive patterns 1020a of the die 1000 prior to the attachment of the die 1000 to the redistribution structure 700. For example, the conductive connectors 900 may be formed on the die 1000 first. Then, the die 1000 having the conductive connectors 900 formed thereon is placed on the redistribution structure 700 through a pick-and-place process. Thereafter, a reflow process is performed to securely fix the die 1000 on the redistribution structure 700 through the conductive connectors 900.

Referring to FIG. 1H, an encapsulant 1100 is formed between the redistribution structure 700 and the die 1000 to laterally encapsulate the die 800 and the conductive connectors 900. That is, the die 800 and the conductive connectors 900 are embedded in the encapsulant 1100. In some embodiments, the encapsulant 1100 is formed such that the die 1000 is disposed on the encapsulant 1100. In some embodiments, the encapsulant 1100 and the encapsulant 500 are made of a same material. However, the disclosure is not limited thereto. In some alternative embodiments, the encapsulant 1100 and the encapsulant 500 may be made of different materials. For example, the material of the encapsulant 1100 may include a molding compound, a MUF, a resin (such as epoxy), or the like. In some embodiments, the encapsulant 1100 may further include fillers, but the inclusion of the fillers is optional. In some embodiments, the encapsulant 1100 is formed by a molding process. For example, the encapsulant 1100 may be formed by a compression molding process, an injection molding process, or the like. In some embodiments, the encapsulation of the second die 800 by the encapsulant 1100 and the encapsulation of the conductive connectors 900 by the encapsulant 1100 are performed simultaneously. In other words, the second die 800 and the conductive connectors 900 are encapsulated by the same encapsulant 1100 simultaneously during the same step.

As illustrated in FIG. 1H, the encapsulant 1100 completely covers sidewalls of the conductive connectors 900 and sidewalls of the die 800. Meanwhile, the encapsulant 1100 also wraps around the topmost conductive patterns 704 of the redistribution structure 700 and the conductive joints 420. In some embodiments, the die 1000 is in physical contact with the encapsulant 1100. For example, the interconnect structure 1020 of the die 1000 is in physical contact with the encapsulant 1100. As illustrated in FIG. 1H, a portion of the encapsulant 1100 is sandwiched between the die 1000 and the rear surface 8800 of the die 800. In some embodiments, the portion of the encapsulant 1100 that is sandwiched between the die 1000 and the rear surface 8800 of the die 800 has a thickness t ranging from about 10 μm to about 100 μm.

Referring to FIG. 1H and FIG. 1I, the structure illustrated in FIG. 1H is flipped upside down and is disposed on a carrier C2. Thereafter, the carrier C1 may be removed to accessibly reveal the redistribution structure 100. In some embodiments, the carrier C1 is removed by a suitable process, such as etching, grinding, mechanical peeling-off, or the like. In an embodiment where an adhesive layer (e.g., a LTHC film) is formed on the carrier C1, the carrier C1 is de-bonded by exposing to a laser or UV light. The laser or UV light breaks the chemical bonds of the adhesive layer that binds to the carrier C1, and the carrier C1 may then be de-bonded. Residues of the adhesive layer, if any, may be removed by a cleaning process performed after the carrier de-bonding process. In some embodiments, the carrier C2 in FIG. 1I is similar to the carrier C1 in FIG. 1A, so the detailed description thereof is omitted herein. In some embodiments, an adhesive layer (not shown) is formed between the carrier C2 and the die 1000. The adhesive layer may be detached from the carrier C2 by, e.g., shining an UV light on the carrier C2 in a subsequent carrier de-bonding process. For example, the adhesive layer is a LTHC coating layer or the like.

Referring to FIG. 1J, a plurality of under-ball metallurgy (UBM) patterns 1200a and a plurality of UBM patterns 1200b are formed on the redistribution structure 100. For example, the UBM patterns 1200a and the UBM patterns 1200b are formed to be in physical contact with the topmost conductive vias 106 of the redistribution structure 100 shown in FIG. 1J, so as to render electrical connection with the redistribution structure 100. In some embodiments, a material of the UBM patterns 1200a and the UBM patterns 1200b includes aluminum, titanium, copper, nickel, tungsten, or alloys thereof. The UBM patterns 1200a and the UBM patterns 1200b may be formed by electroplating, deposition, and/or photolithography and etching. In some embodiments, a size of each UBM pattern 1200a is larger than a size of each UBM patterns 1200b.

After the UBM patterns 1200a and the UBM patterns 1200b are formed on the redistribution structure 100, a plurality of conductive terminals 1300 is placed on the UBM patterns 1200a and a passive component 1400 is mounted on the UBM patterns 1200b. In some embodiments, the conductive terminals 1300 include solder balls. On the other hand, the passive component 1400 is, for example, capacitors, resistors, inductors, antennas, the like, or a combination thereof. In some embodiments, the conductive terminals 1300 may be placed on the UBM patterns 1200a through a ball placement process. Meanwhile, the passive component 1400 may be mounted on the UBM patterns 1200b through a soldering process and/or a reflowing process. For example, the passive component 1400 is attached to the UBM patterns 1200b through conductive joints 430. In some embodiments, the conductive joints 430 include solder joints or the like, so as to securely fix the passive component 1400 on the UBM patterns 1200b. In some embodiments, the conductive terminals 1300 and the passive component 1400 are electrically connected to the redistribution structure 100 respectively through the UBM patterns 1200a and the UBM patterns 1200b.

Referring to FIG. 1J and FIG. 1K, the structure illustrated in FIG. 1J is flipped upside down. Thereafter, the carrier C2 may be removed to accessibly reveal the die 1000. In some embodiments, the carrier C2 is removed by a suitable process, such as etching, grinding, mechanical peeling-off, or the like. In an embodiment where an adhesive layer (e.g., a LTHC film) is formed on the carrier C2, the carrier C2 is de-bonded by exposing to a laser or UV light. The laser or UV light breaks the chemical bonds of the adhesive layer that binds to the carrier C2, and the carrier C2 may then be de-bonded. Residues of the adhesive layer, if any, may be removed by a cleaning process performed after the carrier de-bonding process.

In some embodiments, the previous processes are performed at wafer level, and a singulation process may be performed after the carrier C2 is removed, so as to obtain a plurality of semiconductor packages 10 shown in FIG. 1K. In some embodiments, the singulation process typically involves dicing with a rotation blade and/or a laser beam. In other words, the singulation process includes a laser cutting process, a mechanical cutting process, a laser grooving process, other suitable processes, or a combination thereof. For example, a laser grooving process may be performed on the structure illustrated in FIG. 1J (after removal of the carrier C2) to form trenches (not shown) in the said structure. Thereafter, a mechanical cutting process may be performed on the locations of the trenches to cut through the said structure, so as to obtain the semiconductor package 10.

As illustrated in FIG. 1K, since the encapsulant 1100 is in physical contact with the die 1000, a distance between the die 1000 and the die 800 is rather small. The small distance between the die 1000 and the die 800 allows creation of an effective heat dissipation path. As such, the heat generated during the operation of the die 300 and the die 800 may be effectively dissipated through the foregoing heat dissipation path, so as to enhance the performance of the semiconductor package 10.

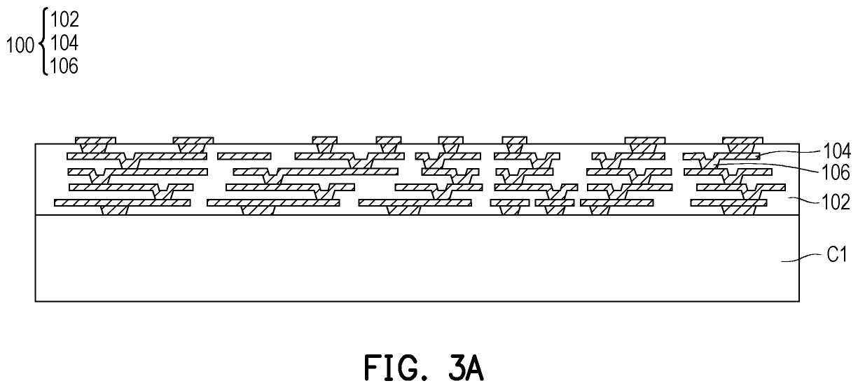

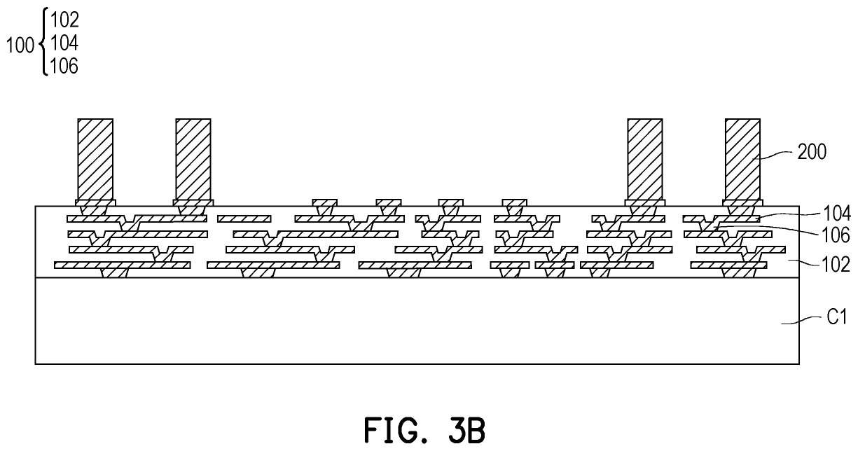

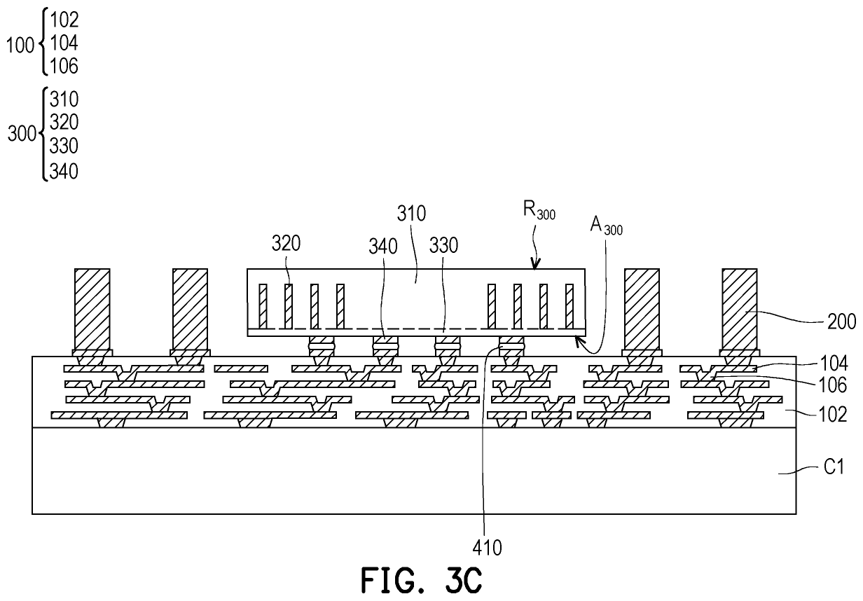

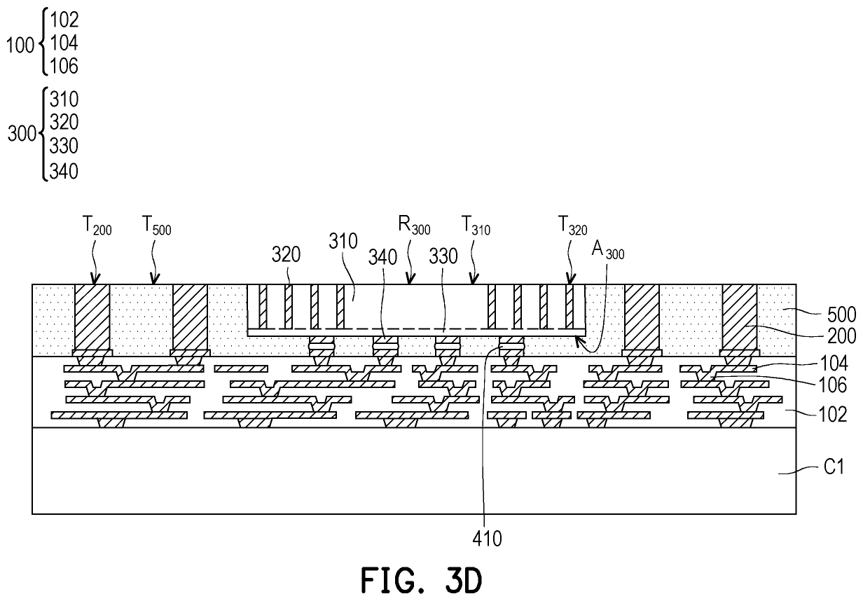

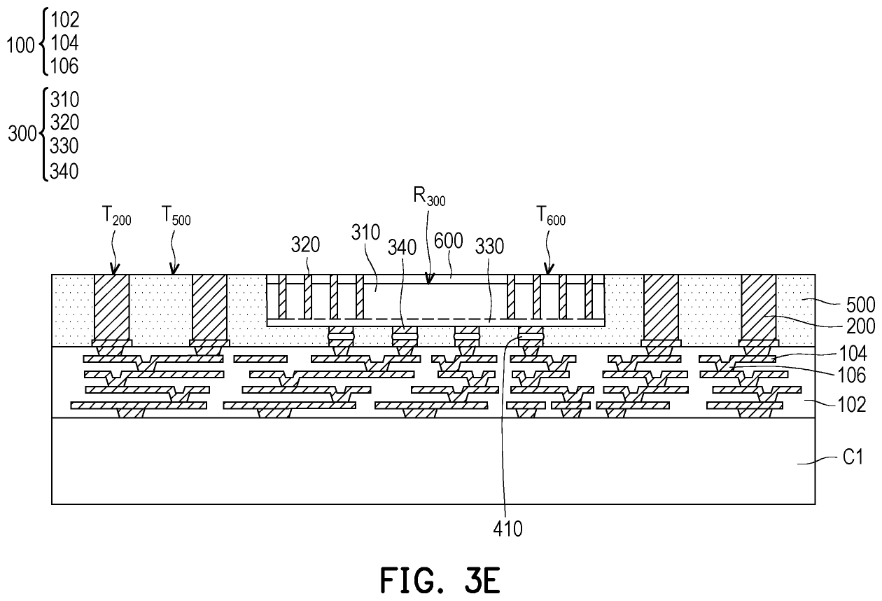

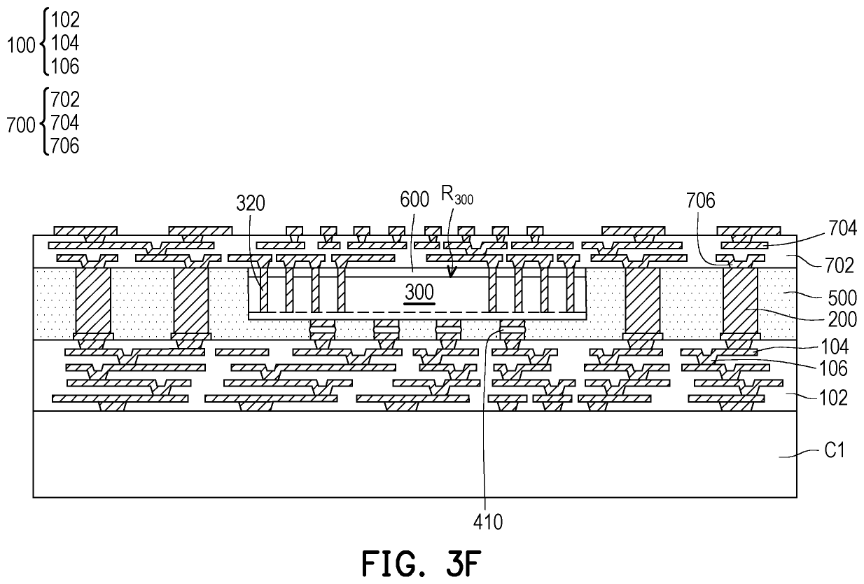

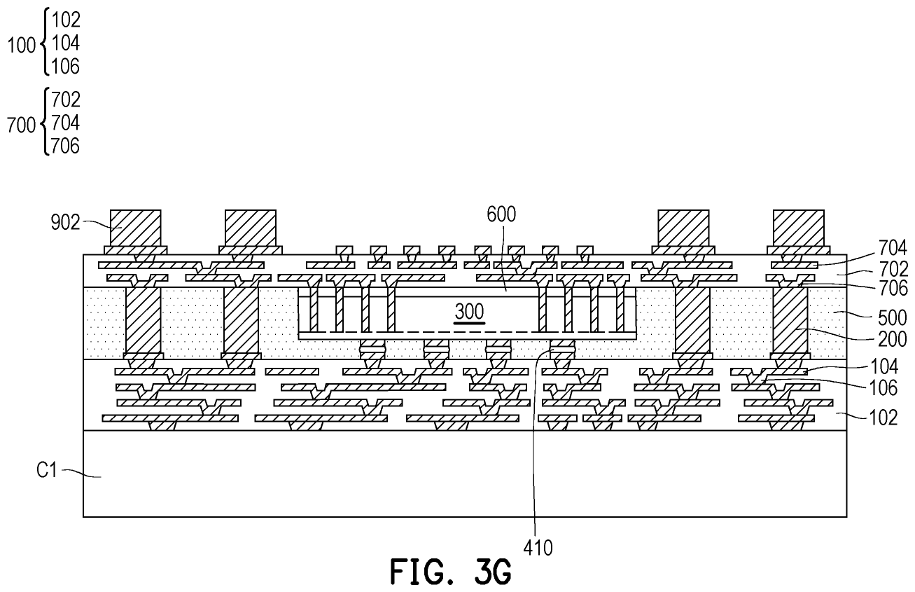

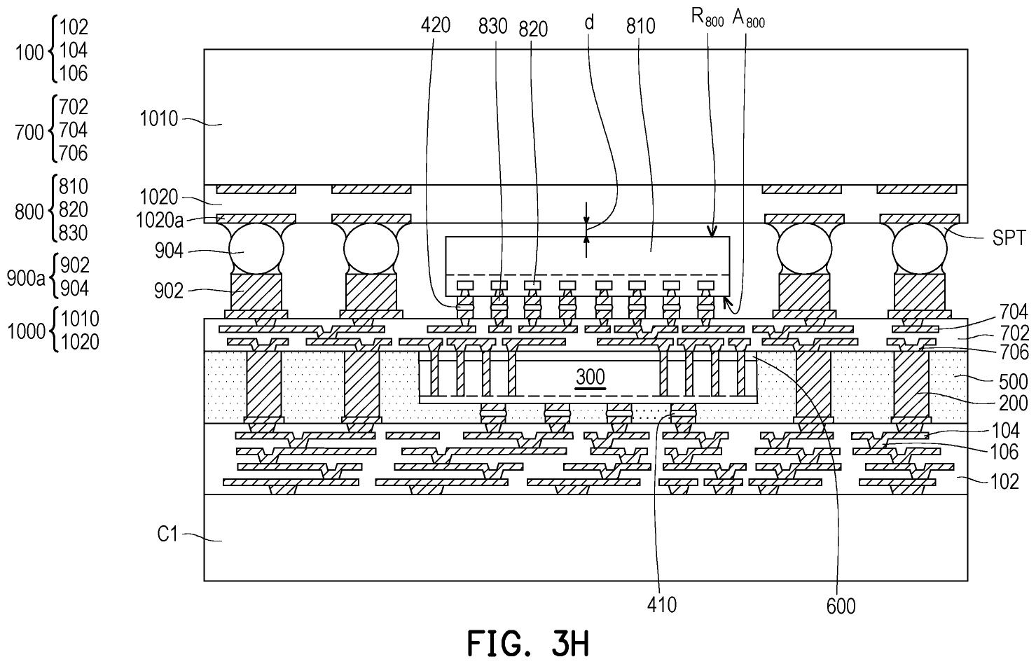

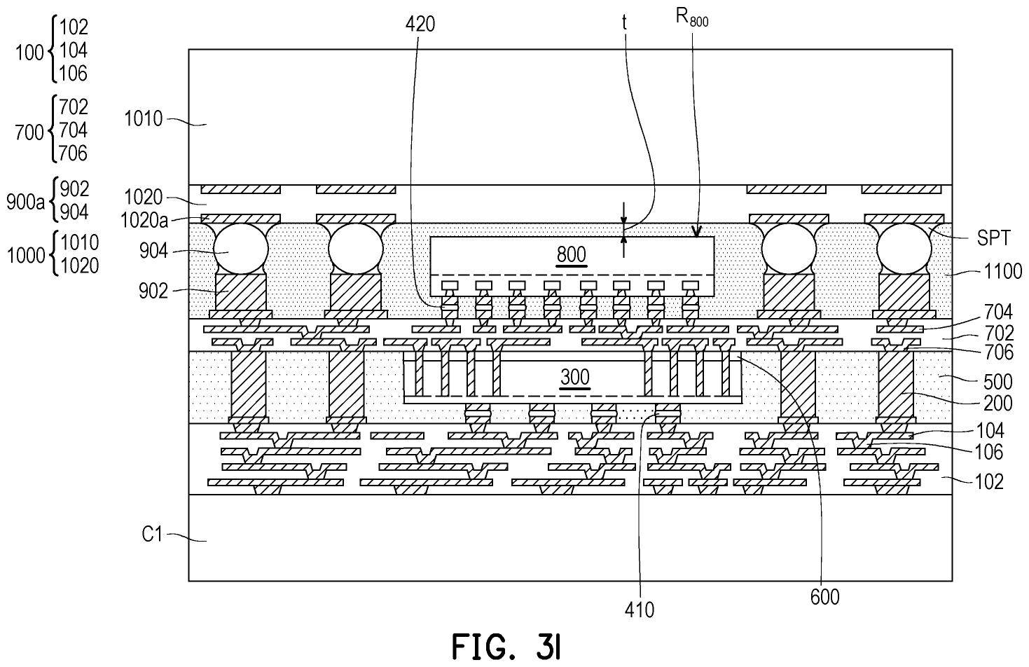

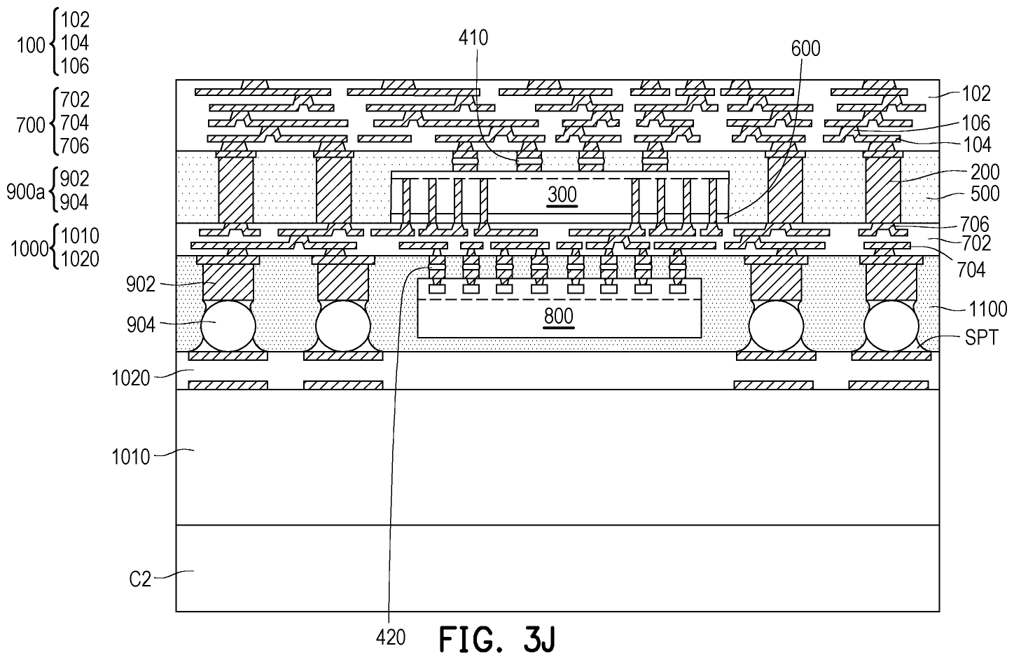

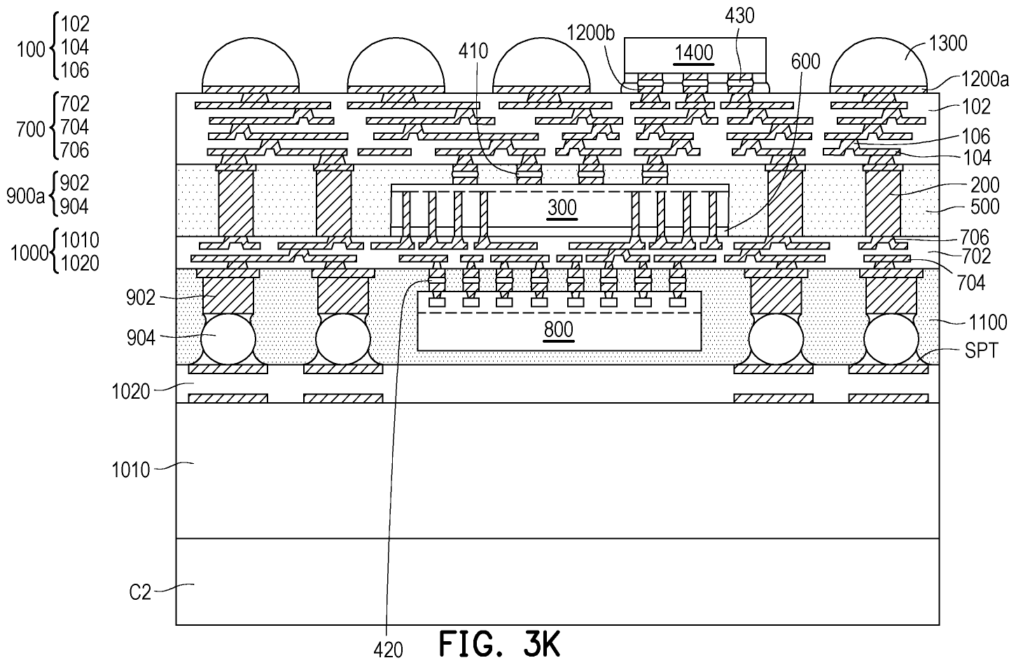

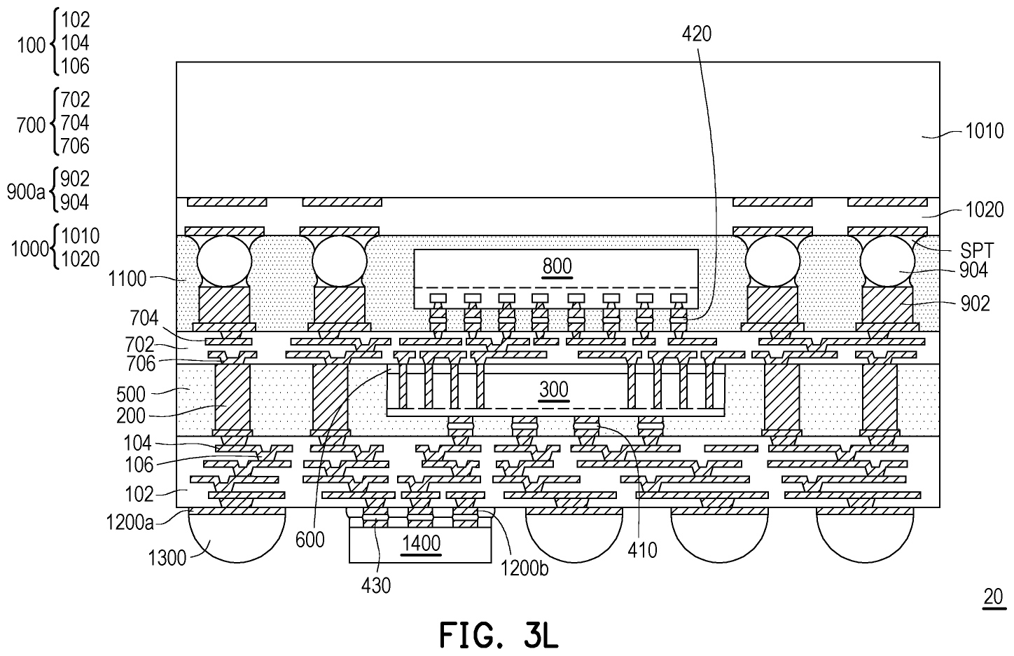

FIG. 3A to FIG. 3L are schematic cross-sectional views illustrating various stages of a manufacturing method of a semiconductor package 20 in accordance with some alternative embodiments of the disclosure. Referring to FIG. 3A to FIG. 3F, the steps shown in FIG. 3A to FIG. 3F are similar to the steps shown in FIG. 1A to FIG. 1F, so similar elements are denoted by the same reference numeral and the detailed descriptions thereof are omitted herein.

Referring to FIG. 3G, a plurality of conductive posts 902 is formed on some of the topmost conductive patterns 704 of the redistribution structure 700. In some embodiments, the conductive posts 902 are in physical contact with the redistribution structure 700. For example, the conductive posts 902 are in physical contact with some of the topmost conductive patterns 704 of the redistribution structure 700. In some embodiments, the conductive posts 902 are formed by the following steps. First, a seed layer (not shown) is conformally formed on the redistribution structure 700. In some embodiments, the seed layer includes a titanium/copper composite layer and is formed by a sputtering process. Then, a patterned photoresist layer (not shown) is formed on the seed layer. In some embodiments, the patterned photoresist layer has a plurality of openings that correspond to locations of the respective conductive posts 902 to be formed. Subsequently, the openings of the patterned photoresist layer are filled with a conductive material. In some embodiments, the conductive material includes copper, copper alloys, or the like. The conductive material is formed by electroplating, deposition, or the like. After the openings are filled with the conductive material, the patterned photoresist layer and the seed layer underneath the patterned photoresist layer are removed through an ashing or a stripping process, so as to obtain the conductive posts 902. In some embodiments, a height of each conductive post 902 ranges from about 80 μm to about 140 μm.

Referring to FIG. 3H, a die 800 is placed on the redistribution structure 700. In some embodiments, the die 800 in FIG. 3H is similar to the die 800 in FIG. 1G, so the detailed description thereof is omitted herein. In some embodiments, the die 800 is placed on the redistribution structure 700 through a pick-and-place process. In some embodiments, the die 800 is attached to the redistribution structure 700 through flip-chip bonding. For example, the connectors 830 of the die 800 may be attached to some of the topmost conductive patterns 704 of the redistribution structure 700 such that the active surface A₈₀₀ of the die 800 faces the redistribution structure 700. Meanwhile, the rear surface 8800 of the die 800 faces upward. In some embodiments, the connectors 830 of the die 800 are attached to the conductive patterns 704 of the redistribution structure 700 through conductive joints 420. In some embodiments, the conductive joints 420 include solder joints or the like, so as to securely fix the die 800 on the redistribution structure 700 and to electrically connect the die 800 and the redistribution structure 700.

After the die 800 is placed on the redistribution structure 700, a die 1000 is provided over the die 800, the redistribution structure 700, and the conductive posts 902. For example, the die 1000 is provided such that the die 800 is located between the redistribution structure 700 and the die 1000. In some embodiments, the die 1000 is provided to be spatially separated from the die 800. For example, a distance d between the die 1000 and the rear surface R₈₀₀ of the die 800 ranges from about 10 μm to about 100 μm. In some embodiments, the die 1000 in FIG. 3H is similar to the die 1000 in FIG. 1G, so the detailed description thereof is omitted herein.

As illustrated in FIG. 3H, the die 1000 is attached to the redistribution structure 700 through a plurality of conductive balls 904 and the conductive posts 902. In some embodiments, the conductive posts 902 and the conductive balls 904 are collectively referred to as conductive connectors 900a. In other words, each conductive connector 900a is divided into a first portion and a second portion connected to the first portion. The first portion includes the conductive posts 902 and the second portion includes the conductive balls 904. In some embodiments, the conductive balls 904 are in physical contact with the bottommost conductive patterns 1020a of the interconnect structure 1100 of the die 1000. That is, the conductive balls 904 are electrically connected to the die 1000. As illustrated in FIG. 3H, the conductive balls 904 are in physical contact with the conductive posts 902. As such, the die 1000 is electrically connected to the redistribution structure 700 through the conductive posts 902 and the conductive balls 904. In other words, the conductive connectors 900a electrically connect the redistribution structure 700 and the die 1000. In some embodiments, a solder paste SPT is presented between the conductive balls 904 and the conductive posts 902 and between the conductive balls 904 and the bottommost conductive patterns 1020a of the die 1000 to further strengthen the bonding between these elements. In some embodiments, the conductive balls 904 have same structures as the conductive connectors 900 in FIG. 1G and FIG. 2, so the detailed descriptions thereof are omitted herein. In some embodiments, a diameter of each conductive ball 904 ranges from about 100 μm to about 200 μm.

As illustrated in FIG. 3H, the conductive connectors 900a (i.e. the conductive posts 902 and the conducive balls 904) are located between the redistribution structure 700 and the die 1000. In some embodiments, the conductive connectors 900a are arrange in an array and surround the die 800. For example, the die 800 is located in a central region of the subsequently formed semiconductor package 20 while the conductive connectors 900a are located in a peripheral region of the subsequently formed semiconductor package 20. As illustrated in FIG. 3H, each of the conductive connectors 900a has a non-straight sidewall. For example, at least a portion of each sidewall of each conductive connector 900a is curved.

As mentioned above, the conductive pots 902 are formed on the redistribution structure 700 prior to attachment of the die 1000 to the redistribution structure 700. That is, at least a portion of each conducive connector 900a is formed on the die 1000 prior to the attachment of the die 1000 to the redistribution structure 700. On the other hand, the conductive balls 904 are formed on the conductive patterns 1020a of the die 1000 prior to the attachment of the die 1000 to the redistribution structure 700. For example, the first portion (i.e. the conductive post 902) of each conductive connector 900a is formed on the redistribution structure 700 and the second portion (i.e. the conductive ball 904) of each conductive connector 900a is formed on the die 1000 prior to the attachment of the die 1000 to the redistribution structure 700. In some embodiment, the die 1000 may be attached to the redistribution structure 700 through the following steps. First, the conductive balls 904 are formed on the die 1000. Then, the die 1000 having the conductive balls 904 formed thereon is placed on the conductive posts 902 through a pick-and-place process. Thereafter, a reflow process is performed to securely fix the conductive balls 904 on the conductive posts 902, so as to connect the die 1000 to the redistribution structure 700 through the conductive connectors 900a.

Referring to FIG. 3I, an encapsulant 1100 is formed between the redistribution structure 700 and the die 1000 to laterally encapsulate the die 800 and the conductive connectors 900a. That is, the die 800 and the conductive connectors 900a are embedded in the encapsulant 1100. In some embodiments, the encapsulant 1100 is formed such that the die 1000 is disposed on the encapsulant 1100. In some embodiments, the encapsulant 1100 in FIG. 3I is similar to the encapsulant 1100 in FIG. 1H, so the detailed description thereof is omitted herein. In some embodiments, the encapsulation of the second die 800 by the encapsulant 1100 and the encapsulation of the conductive connectors 900a by the encapsulant 1100 are performed simultaneously. In other words, the second die 800 and the conductive connectors 900a are encapsulated by the same encapsulant 1100 simultaneously during the same step.

As illustrated in FIG. 3I, the encapsulant 1100 completely covers sidewalls of the conductive connectors 900a and sidewalls of the die 800. For example, the encapsulant 1100 completely covers sidewalls of the conductive posts 902 and sidewalls of the conductive balls 904. Meanwhile, the encapsulant 1100 also wraps around the topmost conductive patterns 704 of the redistribution structure 700 and the conductive joints 420. In some embodiments, the die 1000 is in physical contact with the encapsulant 1100. For example, the interconnect structure 1020 of the die 1000 is in physical contact with the encapsulant 1100. As illustrated in FIG. 3I, a portion of the encapsulant 1100 is sandwiched between the die 1000 and the rear surface 8800 of the die 800. In some embodiments, the portion of the encapsulant 1100 that is sandwiched between the die 1000 and the rear surface R₈₀₀ of the die 800 has a thickness t ranging from about 10 μm to about 100 μm.

Referring to FIG. 3J to FIG. 3L, the steps shown FIG. 3J to FIG. 3L are similar to the steps shown in FIG. 1I to FIG. 1K, so similar elements are denoted by the same reference numeral and the detailed descriptions thereof are omitted herein. As illustrated in FIG. 3L, the semiconductor package 20 is obtained. Since the encapsulant 1100 is in physical contact with the die 1000, a distance between the die 1000 and the die 800 is rather small. The small distance between the die 1000 and the die 800 allows creation of an effective heat dissipation path. As such, the heat generated during the operation of the die 300 and the die 800 may be effectively dissipated through the foregoing heat dissipation path, so as to enhance the performance of the semiconductor package 20.

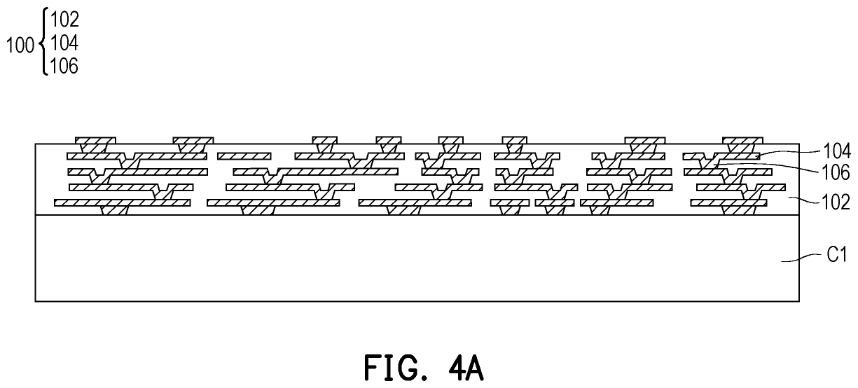

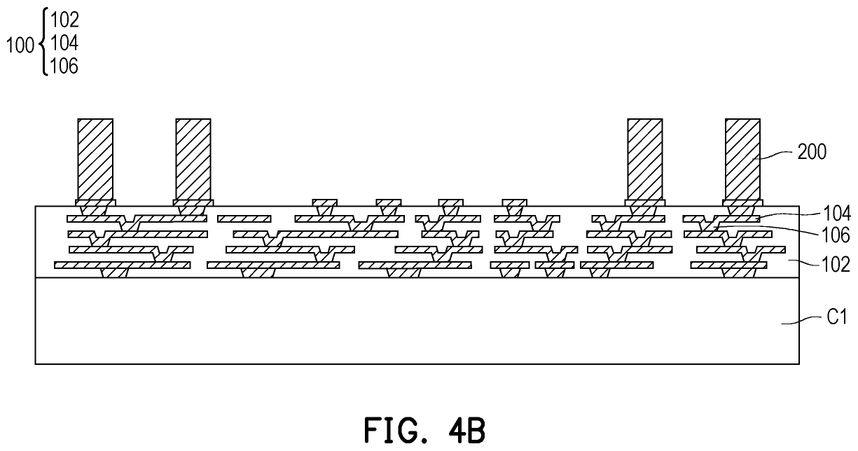

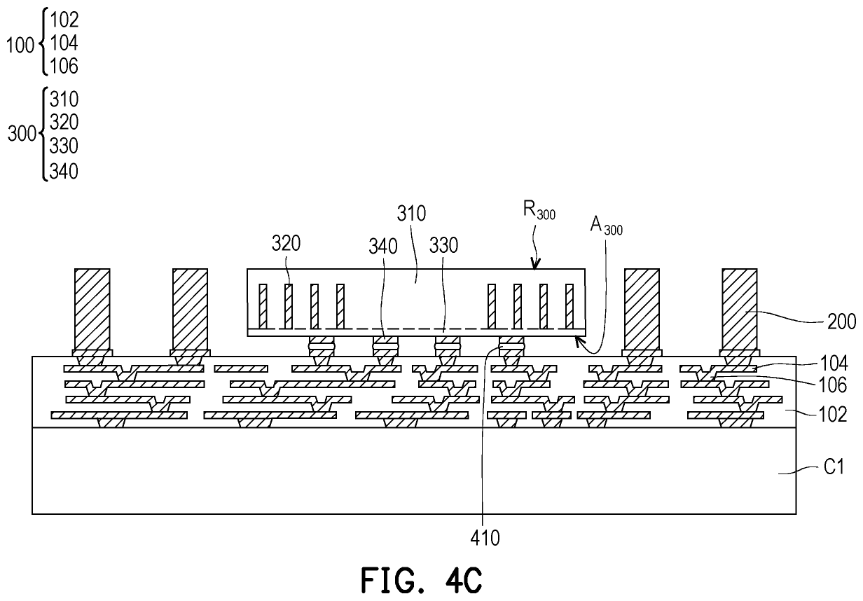

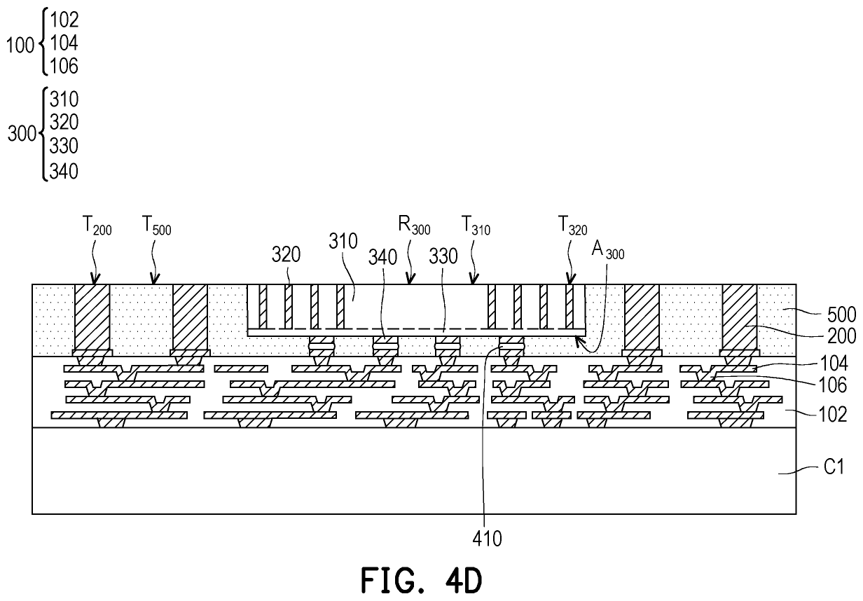

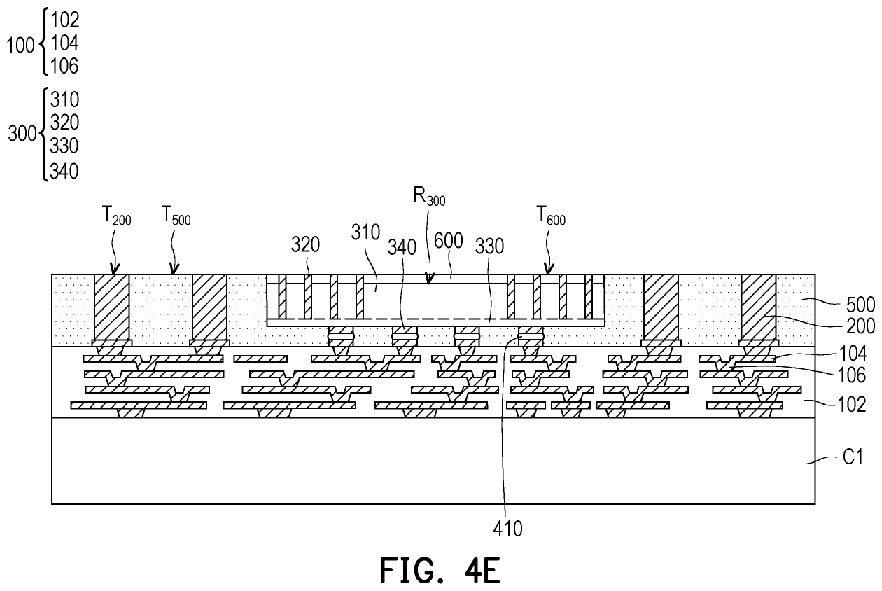

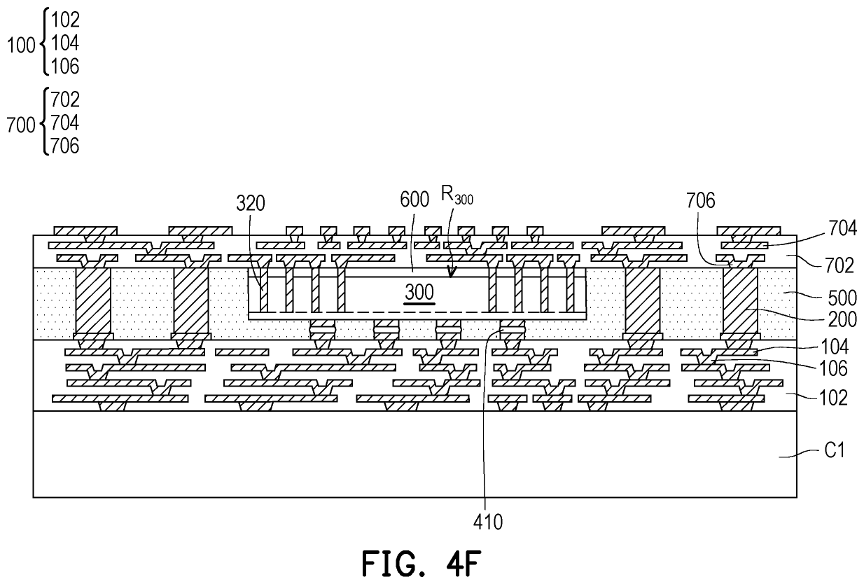

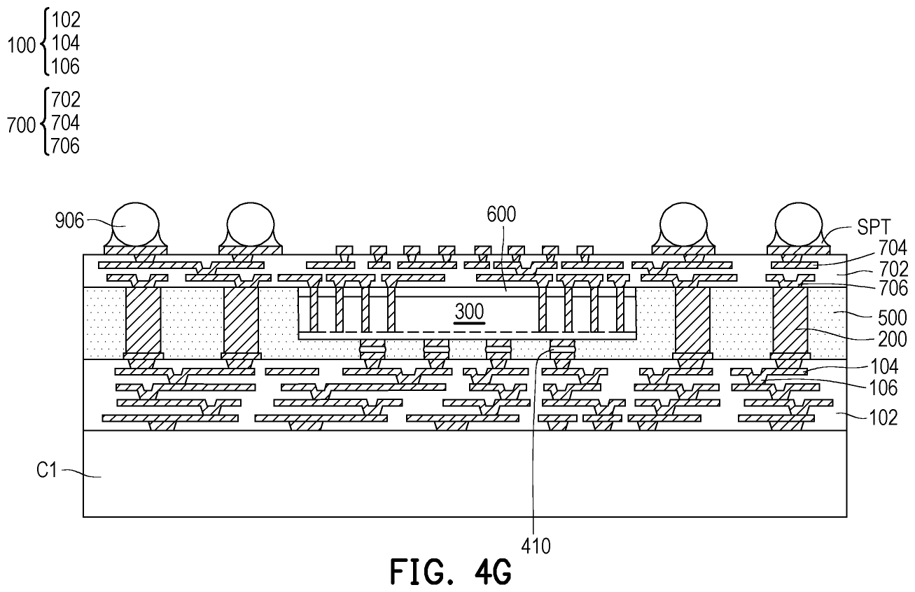

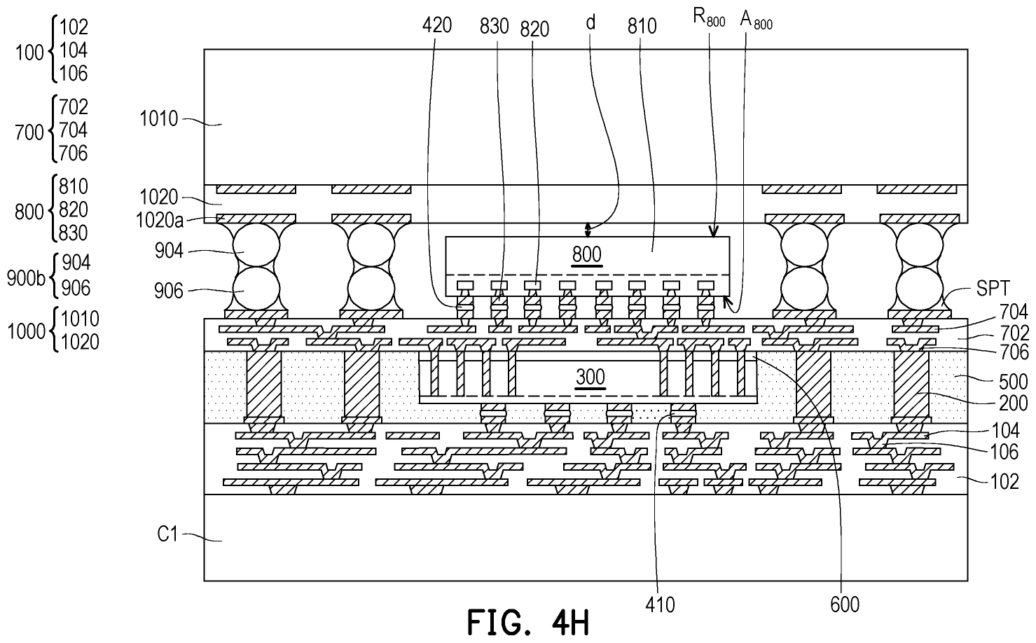

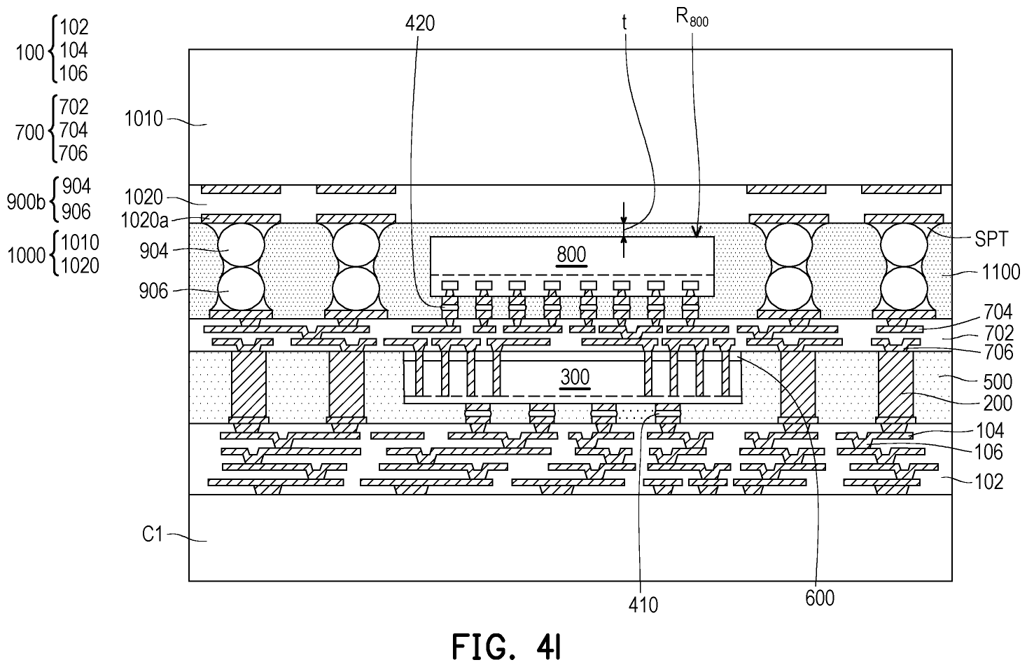

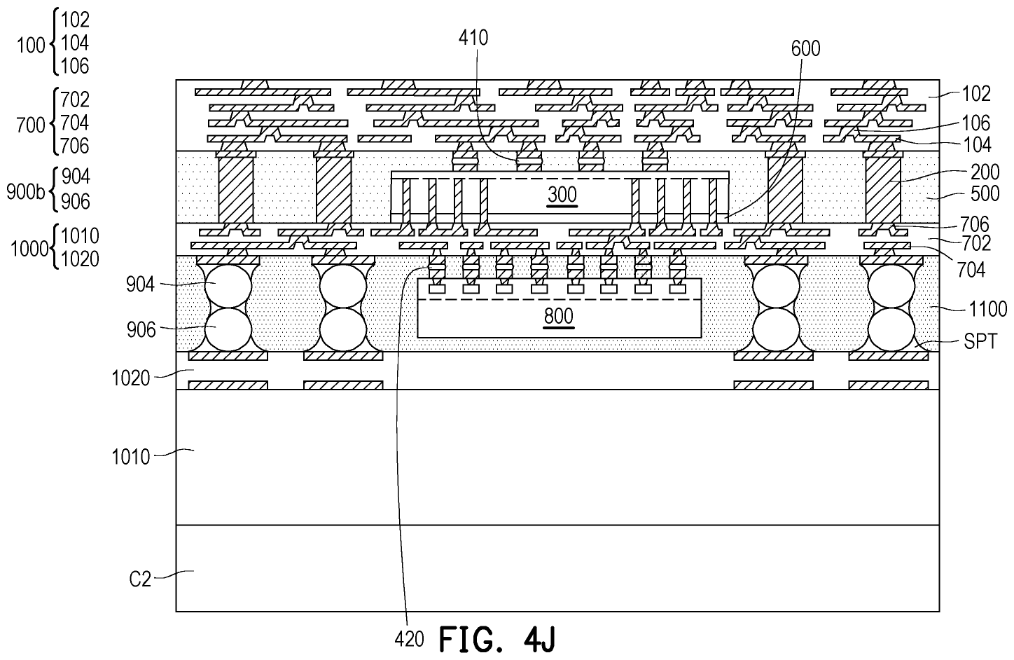

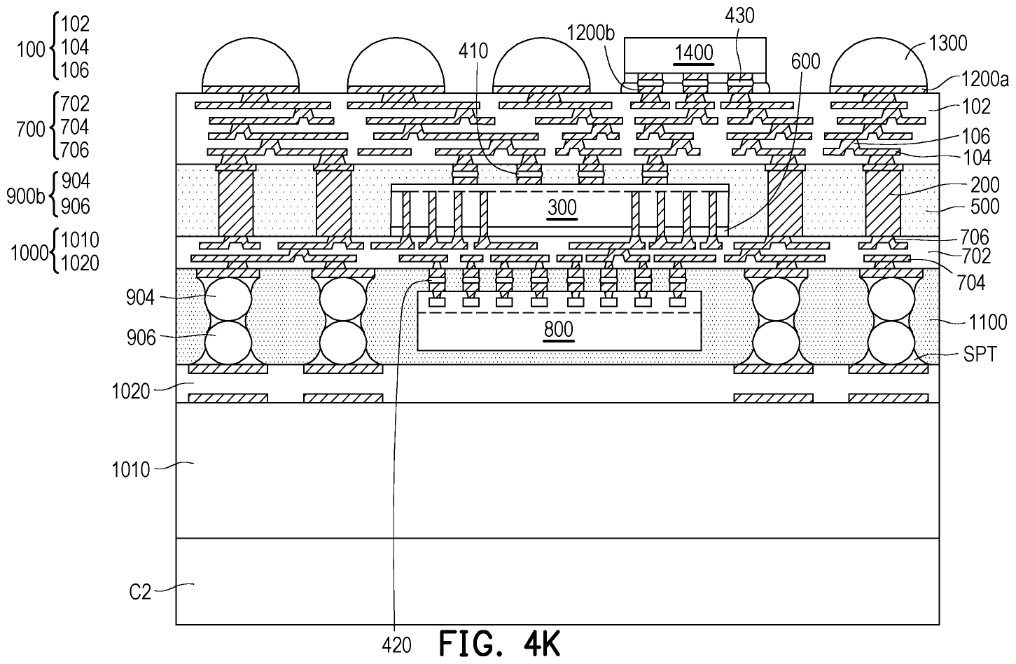

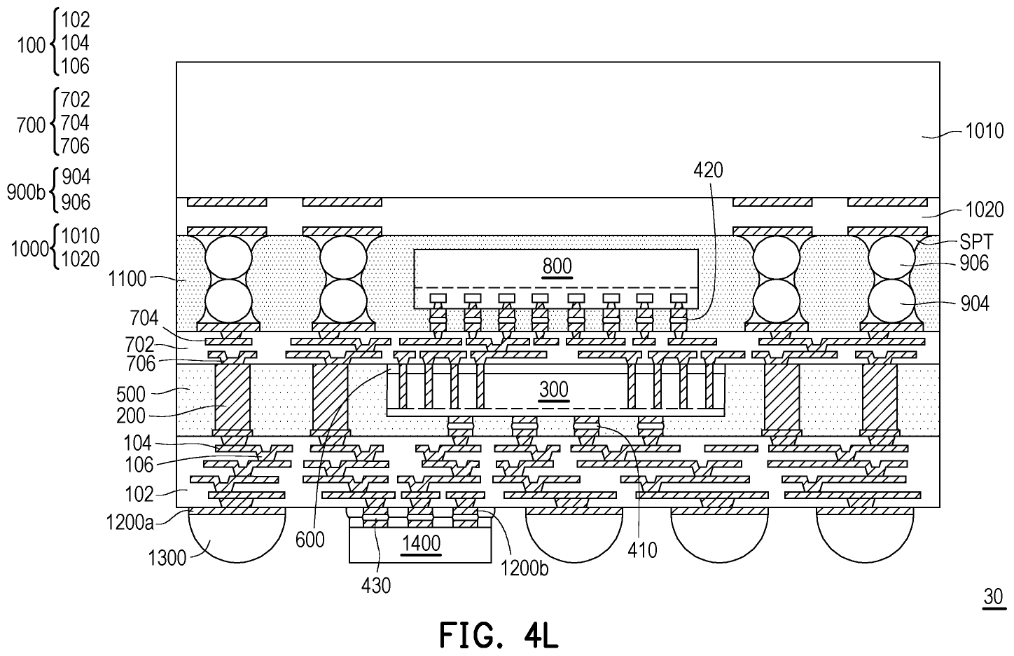

FIG. 4A to FIG. 4L are schematic cross-sectional views illustrating various stages of a manufacturing method of a semiconductor package 30 in accordance with some alternative embodiments of the disclosure. Referring to FIG. 4A to FIG. 4F, the steps shown in FIG. 4A to FIG. 4F are similar to the steps shown in FIG. 1A to FIG. 1F, so similar elements are denoted by the same reference numeral and the detailed descriptions thereof are omitted herein.

Referring to FIG. 4G, a plurality of conductive balls 906 is formed on some of the topmost conductive patterns 704 of the redistribution structure 700. In some embodiments, the conductive balls 906 are in physical contact with the redistribution structure 700. For example, the conductive balls 906 are in physical contact with some of the topmost conductive patterns 704 of the redistribution structure 700. In some embodiments, the conductive balls 906 are formed by a ball placement process or the like. In some embodiments, the conductive balls 906 have same structures as the conductive connectors 900 in FIG. 1G and FIG. 2, so the detailed descriptions thereof are omitted herein. In some embodiments, a diameter of each conductive ball 906 ranges from about 100 μm to about 200 μm. In some embodiments, a solder paste SPT is presented between the conductive balls 906 and some of the topmost conductive patterns 704 of the redistribution structure 700 to further strengthen the bonding between these elements.

Referring to FIG. 4H, a die 800 is placed on the redistribution structure 700. In some embodiments, the die 800 in FIG. 4H is similar to the die 800 in FIG. 1G, so the detailed description thereof is omitted herein. In some embodiments, the die 800 is placed on the redistribution structure 700 through a pick-and-place process. In some embodiments, the die 800 is attached to the redistribution structure 700 through flip-chip bonding. For example, the connectors 830 of the die 800 may be attached to some of the topmost conductive patterns 704 of the redistribution structure 700 such that the active surface A₈₀₀ of the die 800 faces the redistribution structure 700. Meanwhile, the rear surface 8800 of the die 800 faces upward. In some embodiments, the connectors 830 of the die 800 are attached to the conductive patterns 704 of the redistribution structure 700 through conductive joints 420. In some embodiments, the conductive joints 420 include solder joints or the like, so as to securely fix the die 800 on the redistribution structure 700 and to electrically connect the die 800 and the redistribution structure 700.

After the die 800 is placed on the redistribution structure 700, a die 1000 is provided over the die 800, the redistribution structure 700, and the conductive balls 906. For example, the die 1000 is provided such that the die 800 is located between the redistribution structure 700 and the die 1000. In some embodiments, the die 1000 is provided to be spatially separated from the die 800. For example, a distance d between the die 1000 and the rear surface R₈₀₀ of the die 800 ranges from about 10 μm to about 100 μm. In some embodiments, the die 1000 in FIG. 4H is similar to the die 1000 in FIG. 1G, so the detailed description thereof is omitted herein.

As illustrated in FIG. 4H, the die 1000 is attached to the redistribution structure 700 through a plurality of conductive balls 904 and the conductive balls 906. In some embodiments, the conductive balls 906 and the conductive balls 904 are collectively referred to as conductive connectors 900b. In other words, each conductive connector 900b is divided into a first portion and a second portion connected to the first portion. The first portion includes the conductive balls 906 and the second portion includes the conductive balls 904. In some embodiments, the conductive balls 904 are in physical contact with the bottommost conductive patterns 1020a of the interconnect structure 1100 of the die 1000. That is, the conductive balls 904 are electrically connected to the die 1000. As illustrated in FIG. 4H, the conductive balls 904 are in physical contact with the conductive balls 906. As such, the die 1000 is electrically connected to the redistribution structure 700 through the conductive balls 906 and the conductive balls 904. In other words, the conductive connectors 900b electrically connect the redistribution structure 700 and the die 1000. In some embodiments, the solder paste SPT is further presented between the conductive balls 904 and the conductive balls 906 and between the conductive balls 904 and the bottommost conductive patterns 1020a of the die 1000 to further strengthen the bonding between these elements. In some embodiments, the conductive balls 904 have same structures as the conductive connectors 900 in FIG. 1G and FIG. 2, so the detailed descriptions thereof are omitted herein. In some embodiments, a diameter of each conductive ball 904 ranges from about 100 μm to about 200 μm.

As illustrated in FIG. 4H, the conductive connectors 900b (i.e. the conductive balls 906 and the conducive balls 904) are located between the redistribution structure 700 and the die 1000. In some embodiments, the conductive connectors 900b are arrange in an array and surround the die 800. For example, the die 800 is located in a central region of the subsequently formed semiconductor package 30 while the conductive connectors 900b are located in a peripheral region of the subsequently formed semiconductor package 30. As illustrated in FIG. 4H, each of the conductive connectors 900b has a non-straight sidewall. For example, each sidewall of each conductive connector 900b is curved.

As mentioned above, the conductive balls 906 are formed on the redistribution structure 700 prior to attachment of the die 1000 to the redistribution structure 700. That is, at least a portion of each conducive connector 900b is formed on the die 1000 prior to the attachment of the die 1000 to the redistribution structure 700. On the other hand, the conductive balls 904 are formed on the conductive patterns 1020a of the die 1000 prior to the attachment of the die 1000 to the redistribution structure 700. For example, the first portion (i.e. the conductive balls 906) of each conductive connector 900b is formed on the redistribution structure 700 and the second portion (i.e. the conductive ball 904) of each conductive connector 900b is formed on the die 1000 prior to the attachment of the die 1000 to the redistribution structure 700. In some embodiment, the die 1000 may be attached to the redistribution structure 700 through the following steps. First, the conductive balls 904 are formed on the die 1000. Then, the die 1000 having the conductive balls 904 formed thereon is placed on the conductive balls 906 through a pick-and-place process. Thereafter, a reflow process is performed to securely fix the conductive balls 904 on the conductive balls 906, so as to connect the die 1000 to the redistribution structure 700 through the conductive connectors 900b.

Referring to FIG. 4I, an encapsulant 1100 is formed between the redistribution structure 700 and the die 1000 to laterally encapsulate the die 800 and the conductive connectors 900b. That is, the die 800 and the conductive connectors 900b are embedded in the encapsulant 1100. In some embodiments, the encapsulant 1100 is formed such that the die 1000 is disposed on the encapsulant 1100. In some embodiments, the encapsulant 1100 in FIG. 4I is similar to the encapsulant 1100 in FIG. 1H, so the detailed description thereof is omitted herein. In some embodiments, the encapsulation of the second die 800 by the encapsulant 1100 and the encapsulation of the conductive connectors 900b by the encapsulant 1100 are performed simultaneously. In other words, the second die 800 and the conductive connectors 900b are encapsulated by the same encapsulant 1100 simultaneously during the same step.

As illustrated in FIG. 4I, the encapsulant 1100 completely covers sidewalls of the conductive connectors 900b and sidewalls of the die 800. For example, the encapsulant 1100 completely covers sidewalls of the conductive balls 906 and sidewalls of the conductive balls 904. Meanwhile, the encapsulant 1100 also wraps around the topmost conductive patterns 704 of the redistribution structure 700 and the conductive joints 420. In some embodiments, the die 1000 is in physical contact with the encapsulant 1100. For example, the interconnect structure 1020 of the die 1000 is in physical contact with the encapsulant 1100. As illustrated in FIG. 4I, a portion of the encapsulant 1100 is sandwiched between the die 1000 and the rear surface 8800 of the die 800. In some embodiments, the portion of the encapsulant 1100 that is sandwiched between the die 1000 and the rear surface R₈₀₀ of the die 800 has a thickness t ranging from about 10 μm to about 100 μm.

Referring to FIG. 4J to FIG. 4L, the steps shown FIG. 4J to FIG. 4L are similar to the steps shown in FIG. 1I to FIG. 1K, so similar elements are denoted by the same reference numeral and the detailed descriptions thereof are omitted herein. As illustrated in FIG. 4L, the semiconductor package 30 is obtained. Since the encapsulant 1100 is in physical contact with the die 1000, a distance between the die 1000 and the die 800 is rather small. The small distance between the die 1000 and the die 800 allows creation of an effective heat dissipation path. As such, the heat generated during the operation of the die 300 and the die 800 may be effectively dissipated through the foregoing heat dissipation path, so as to enhance the performance of the semiconductor package 30.

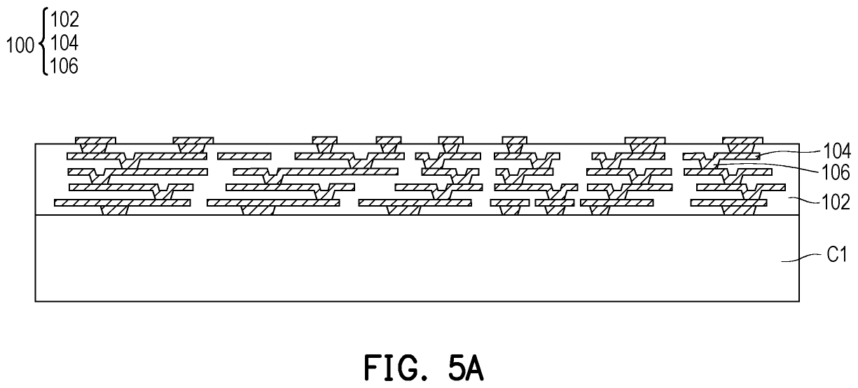

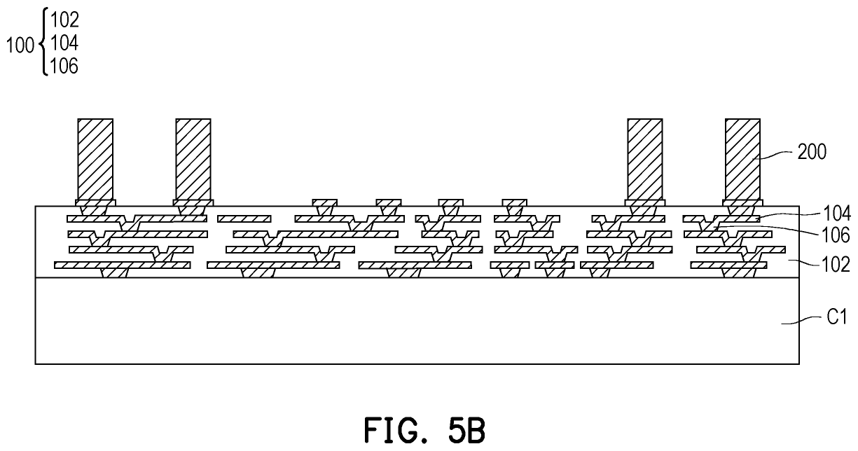

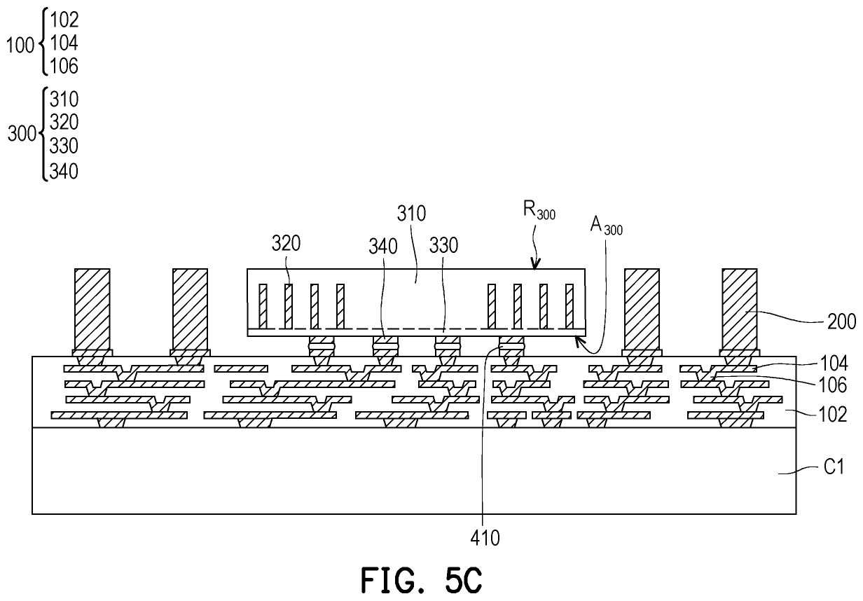

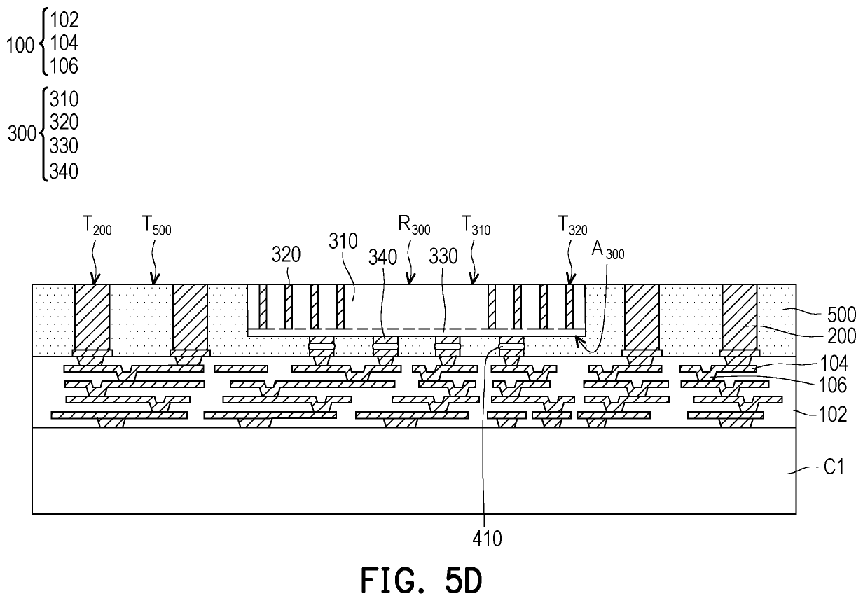

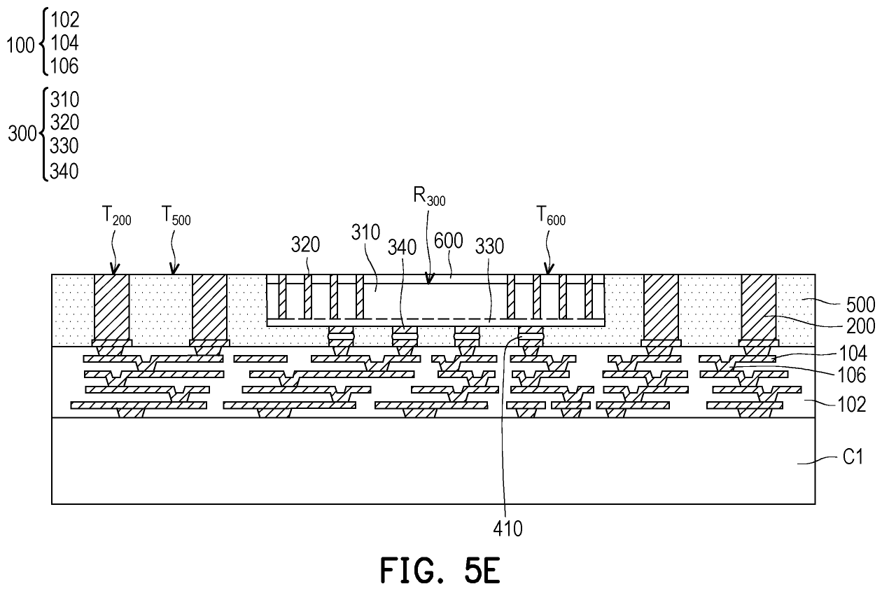

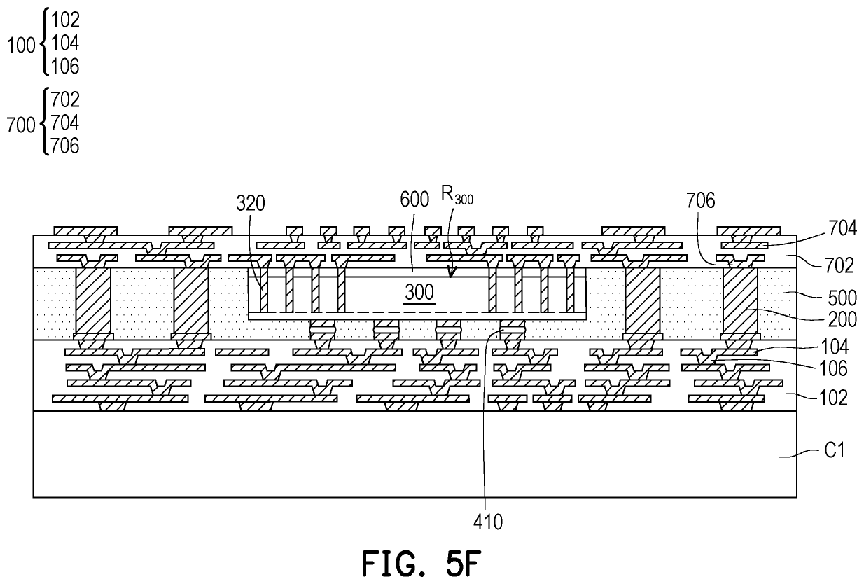

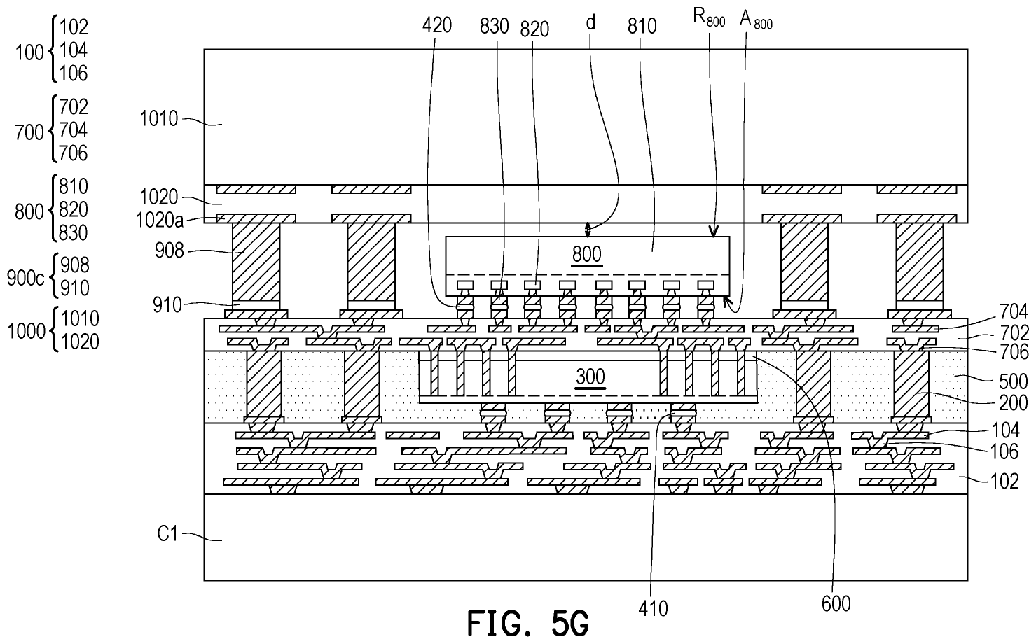

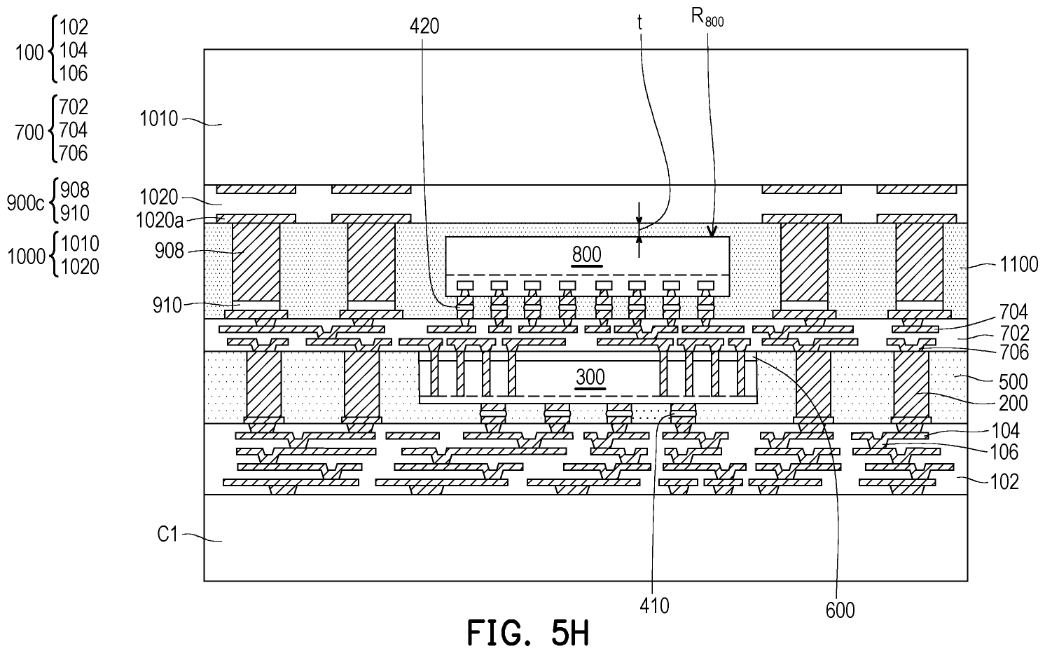

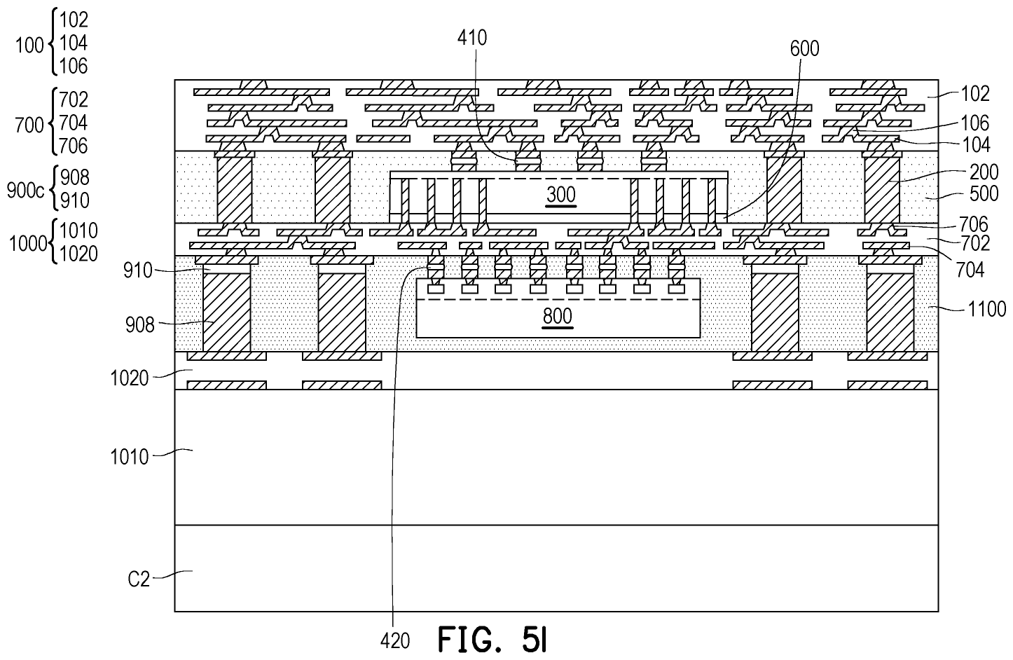

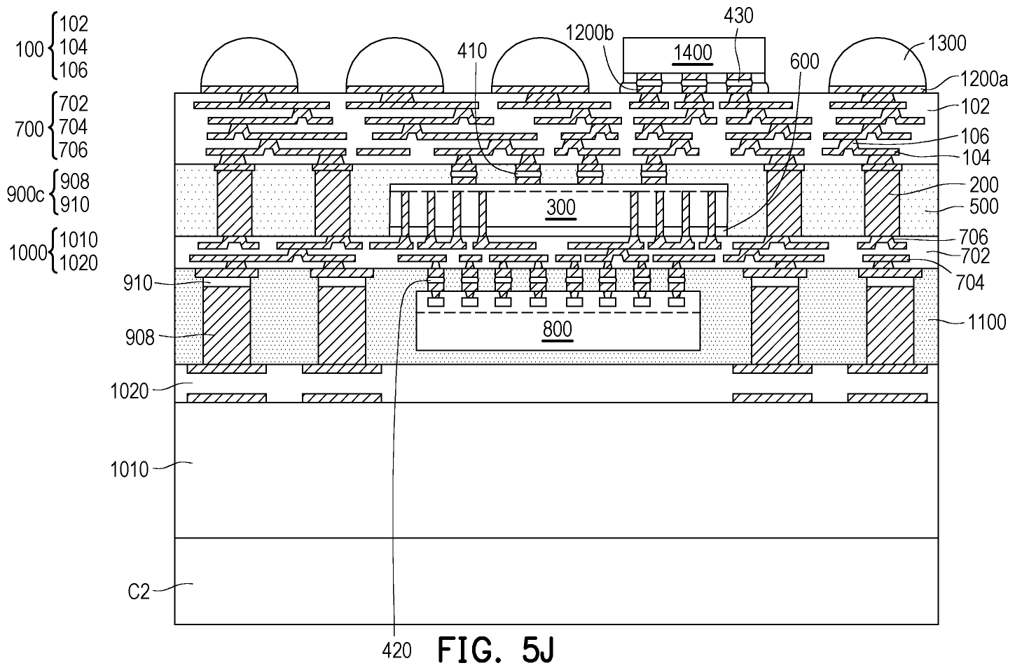

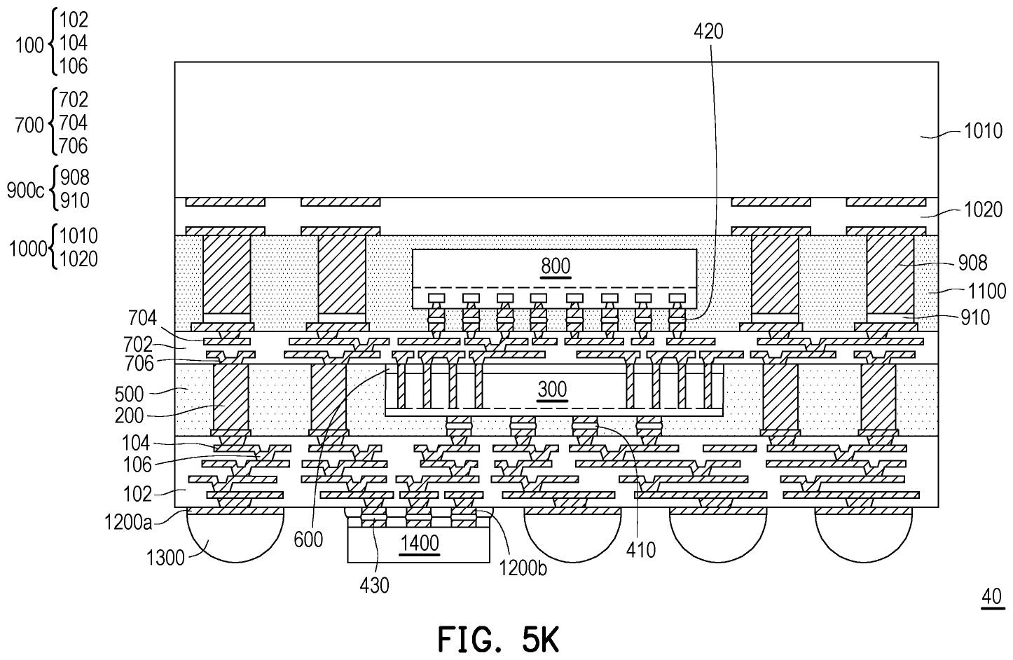

FIG. 5A to FIG. 5K are schematic cross-sectional views illustrating various stages of a manufacturing method of a semiconductor package 40 in accordance with some alternative embodiments of the disclosure. Referring to FIG. 5A to FIG. 5F, the steps shown in FIG. 5A to FIG. 5F are similar to the steps shown in FIG. 1A to FIG. 1F, so similar elements are denoted by the same reference numeral and the detailed descriptions thereof are omitted herein.

Referring to FIG. 5G, a die 800 is placed on the redistribution structure 700. In some embodiments, the die 800 in FIG. 5G is similar to the die 800 in FIG. 1G, so the detailed description thereof is omitted herein. In some embodiments, the die 800 is placed on the redistribution structure 700 through a pick-and-place process. In some embodiments, the die 800 is attached to the redistribution structure 700 through flip-chip bonding. For example, the connectors 830 of the die 800 may be attached to some of the topmost conductive patterns 704 of the redistribution structure 700 such that the active surface A₈₀₀ of the die 800 faces the redistribution structure 700. Meanwhile, the rear surface 8800 of the die 800 faces upward. In some embodiments, the connectors 830 of the die 800 are attached to the conductive patterns 704 of the redistribution structure 700 through conductive joints 420. In some embodiments, the conductive joints 420 include solder joints or the like, so as to securely fix the die 800 on the redistribution structure 700 and to electrically connect the die 800 and the redistribution structure 700.

After the die 800 is placed on the redistribution structure 700, a die 1000 is provided over the die 800 and the redistribution structure 700. For example, the die 1000 is provided such that the die 800 is located between the redistribution structure 700 and the die 1000. In some embodiments, the die 1000 is provided to be spatially separated from the die 800. For example, a distance d between the die 1000 and the rear surface R₈₀₀ of the die 800 ranges from about 10 μm to about 100 μm. In some embodiments, the die 1000 in FIG. 5G is similar to the die 1000 in FIG. 1G, so the detailed description thereof is omitted herein.

As illustrated in FIG. 5G, the die 1000 is attached to the redistribution structure 700 through a plurality of conductive connectors 900c. In some embodiments, each conductive connector 900c includes a conducive post 908 and a conductive cap 910. In other words, each conductive connector 900c is divided into a first portion and a second portion connected to the first portion. The first portion includes the conductive caps 910 and the second portion includes the conductive posts 908. In some embodiments, the conductive posts 908 are in physical contact with the bottommost conductive patterns 1020a of the interconnect structure 1100 of the die 1000. That is, the conductive posts 908 are electrically connected to the die 1000. Meanwhile, the conductive caps 910 are in physical contact with some of the topmost conductive patterns 704 of the redistribution structure 700. As illustrated in FIG. 5G, the conductive posts 908 are in physical contact with the conductive caps 910. As such, the die 1000 is electrically connected to the redistribution structure 700 through the conductive posts 908 and the conductive caps 910. In other words, the conductive connectors 900c electrically connect the redistribution structure 700 and the die 1000.

In some embodiments, a material of the conductive posts 908 includes copper, copper alloys, titanium, titanium alloy, a combination thereof, or the like. In some embodiments, a height of each conductive post 908 ranges from about 200 μm to about 700 lam. In some embodiments, a material of the conductive cap 910 includes solder or the like. In some embodiments, a height of each conductive cap 910 ranges from about 2 μm to about 20 μm.

As illustrated in FIG. 5G, the conductive connectors 900c (i.e. the conductive posts 908 and the conducive caps 910) are located between the redistribution structure 700 and the die 1000. In some embodiments, the conductive connectors 900c are arrange in an array and surround the die 800. For example, the die 800 is located in a central region of the subsequently formed semiconductor package 40 while the conductive connectors 900c are located in a peripheral region of the subsequently formed semiconductor package 40.

In some embodiments, the conductive connectors 900c are formed on the conductive patterns 1020a of the die 1000 prior to the attachment of the die 1000 to the redistribution structure 700. For example, the conductive posts 908 may be formed on the conductive patterns 1020a of the interconnect structure 1020 of the die 1000. In some embodiments, the conductive posts 908 are pre-formed and are placed on the die 1000 through a pick-and-place process or the like. However, the disclosure is not limited thereto. In some embodiments, the conductive posts 908 may be formed on the die 1000 through a plating process or the like. In some embodiments, the conductive posts 908 formed on the die 1000 are referred to as a pin grid array (PGA). After the conductive posts 908 are formed on the die 1000, the conductive caps 910 are disposed on the conductive posts 908, so as to form the conductive connectors 900c on the die 1000. In some embodiments, the conductive caps 910 may be in a paste form and are coated on top surfaces of the conductive posts 908. Subsequently, the die 1000 having the conductive connectors 900c formed thereon is placed on the redistribution structure 700 through a pick-and-place process. Thereafter, a reflow process is performed to securely fix the die 1000 on the redistribution structure 700 through the conductive connectors 900c.

Referring to FIG. 5H, an encapsulant 1100 is formed between the redistribution structure 700 and the die 1000 to laterally encapsulate the die 800 and the conductive connectors 900c. That is, the die 800 and the conductive connectors 900c are embedded in the encapsulant 1100. In some embodiments, the encapsulant 1100 is formed such that the die 1000 is disposed on the encapsulant 1100. In some embodiments, the encapsulant 1100 in FIG. 5H is similar to the encapsulant 1100 in FIG. 1H, so the detailed description thereof is omitted herein. In some embodiments, the encapsulation of the second die 800 by the encapsulant 1100 and the encapsulation of the conductive connectors 900c by the encapsulant 1100 are performed simultaneously. In other words, the second die 800 and the conductive connectors 900c are encapsulated by the same encapsulant 1100 simultaneously during the same step.

As illustrated in FIG. 5H, the encapsulant 1100 completely covers sidewalls of the conductive connectors 900c and sidewalls of the die 800. For example, the encapsulant 1100 completely covers sidewalls of the conductive posts 908 and sidewalls of the conductive caps 910. Meanwhile, the encapsulant 1100 also wraps around the topmost conductive patterns 704 of the redistribution structure 700 and the conductive joints 420. In some embodiments, the die 1000 is in physical contact with the encapsulant 1100. For example, the interconnect structure 1020 of the die 1000 is in physical contact with the encapsulant 1100. As illustrated in FIG. 5H, a portion of the encapsulant 1100 is sandwiched between the die 1000 and the rear surface 8800 of the die 800. In some embodiments, the portion of the encapsulant 1100 that is sandwiched between the die 1000 and the rear surface R₈₀₀ of the die 800 has a thickness t ranging from about 10 μm to about 100 μm.

Referring to FIG. 5I to FIG. 5K, the steps shown FIG. SI to FIG. 5K are similar to the steps shown in FIG. 1I to FIG. 1K, so similar elements are denoted by the same reference numeral and the detailed descriptions thereof are omitted herein. As illustrated in FIG. 5K, the semiconductor package 40 is obtained. Since the encapsulant 1100 is in physical contact with the die 1000, a distance between the die 1000 and the die 800 is rather small. The small distance between the die 1000 and the die 800 allows creation of an effective heat dissipation path. As such, the heat generated during the operation of the die 300 and the die 800 may be effectively dissipated through the foregoing heat dissipation path, so as to enhance the performance of the semiconductor package 40.

In accordance with some embodiments of the disclosure, a semiconductor package includes a first redistribution structure, a second redistribution structure, a first die, a first encapsulant, a second die, a second encapsulant, conductive connectors, and a third die. The second redistribution structure is over the first redistribution structure. The first die is located between the first redistribution structure and the second redistribution structure. The first encapsulant laterally encapsulates the first die. The second die is disposed on and electrically connected to the second redistribution structure. The second encapsulant laterally encapsulates the second die. The conductive connectors surround the second die and are embedded in the second encapsulant. The third die is disposed over the second die. The third die is in physical contact with the second encapsulant and the conductive connectors.

In accordance with some alternative embodiments of the disclosure, a semiconductor package includes a first redistribution structure, a first die, a first encapsulant, a second redistribution structure, a second die, conductive connectors, a second encapsulant, and a third die. The first die has an active surface and a rear surface opposite to the active surface. The first die is disposed on and electrically connected to the first redistribution structure. The first encapsulant laterally encapsulates the first die. The second redistribution structure is disposed over the rear surface of the first die. The second die is disposed on and electrically connected to the second redistribution structure. The conductive connectors are disposed on and electrically connected to the second redistribution structure. The second encapsulant laterally encapsulates the conductive connectors and the second die. The second encapsulant completely covers sidewalls of the conductive connectors. The third die is disposed on and in physical contact with the second encapsulant and the conductive connectors.

In accordance with some embodiments of the disclosure, a manufacturing method of a semiconductor package includes at least the following steps. A first redistribution structure is provided. A first die is placed on the first redistribution structure. A first encapsulant is formed on the first redistribution structure to laterally encapsulate the first die. A second redistribution structure is formed over the first die and the first encapsulant. A second die is placed on the second redistribution structure. A third die is attached to the second redistribution structure through conductive connectors. The third die is over the second die. The second die and the conductive connectors are encapsulated by a second encapsulant such that the second encapsulant is in physical contact with the third die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first redistribution structure;
a second redistribution structure over the first redistribution structure;
a first die located between the first redistribution structure and the second redistribution structure;
a first encapsulant laterally encapsulating the first die;
a second die disposed on and electrically connected to the second redistribution structure;
a second encapsulant laterally encapsulating the second die;
conductive connectors surrounding the second die, wherein the conductive connectors are embedded in the second encapsulant; and
a third die disposed over the second die, wherein the third die is in physical contact with the second encapsulant and the conductive connectors.

2. The semiconductor package of claim 1, wherein the third die comprises a semiconductor substrate and an interconnect structure disposed on the semiconductor substrate, and the interconnect structure is in physical contact with the second encapsulant and the conductive connectors.

3. The semiconductor package of claim 1, wherein each of the conductive connectors comprises a conductive ball, one end of the conductive ball is in physical contact with the second redistribution structure, and another end of the conductive ball is in physical contact with the third die.

4. The semiconductor package of claim 3, wherein the conductive ball comprises a copper ball, a nickel layer wrapping around the copper ball, and a solder layer wrapping around the nickel layer.

5. The semiconductor package of claim 1, wherein each of the conductive connectors comprises a conductive post and a conductive ball connected to the conductive post, wherein the conductive post is in physical contact with the second redistribution structure, and the conductive ball is in physical contact with the third die.

6. The semiconductor package of claim 1, wherein each of the conductive connectors comprises a first conductive ball and a second conductive ball connected to the first conductive ball, the first conductive ball is in physical contact with the second redistribution structure, and the second conductive ball is in physical contact with the third die.

7. The semiconductor package of claim 1, wherein each of the conductive connectors comprises a conductive post and a conductive cap connected to the conductive post, the conductive cap is in physical contact with the second redistribution structure, and the conductive post is in physical contact with the third die.

8. The semiconductor package of claim 1, further comprising conductive structures surrounding the first die, wherein the conductive structures penetrate through the first encapsulant to electrically connect the first redistribution structure and the second redistribution structure.

9. The semiconductor package of claim 1, wherein the first encapsulant and the second encapsulant are made of a same material.

10. A semiconductor package, comprising:
a first redistribution structure;
a first die having an active surface and a rear surface opposite to the active surface, wherein the first die is disposed on and electrically connected to the first redistribution structure;
a first encapsulant laterally encapsulating the first die;
a second redistribution structure disposed over the rear surface of the first die;
a second die disposed on and electrically connected to the second redistribution structure;
conductive connectors disposed on and electrically connected to the second redistribution structure;
a second encapsulant laterally encapsulating the conductive connectors and the second die, wherein the second encapsulant completely covers sidewalls of the conductive connectors; and
a third die disposed on and in physical contact with the second encapsulant and the conductive connectors.

11. The semiconductor package of claim 10, wherein the second die has an active surface and a rear surface opposite to the active surface, the active surface of the second die faces the second redistribution structure, and a portion of the second encapsulant is sandwiched between the third die and the rear surface of the second die.

12. The semiconductor package of claim 10, wherein each of the conductive connectors comprises a conductive ball, one end of the conductive ball is in physical contact with the second redistribution structure, and another end of the conductive ball is in physical contact with the third die.

13. The semiconductor package of claim 10, wherein each of the conductive connectors comprises a conductive post and a conductive ball connected to the conductive post, wherein the conductive post is in physical contact with the second redistribution structure, and the conductive ball is in physical contact with the third die.

14. The semiconductor package of claim 10, wherein each of the conductive connectors comprises a first conductive ball and a second conductive ball connected to the first conductive ball, the first conductive ball is in physical contact with the second redistribution structure, and the second conductive ball is in physical contact with the third die.

15. The semiconductor package of claim 10, wherein each of the conductive connectors comprises a conductive post and a conductive cap connected to the conductive post, the conductive cap is in physical contact with the second redistribution structure, and the conductive post is in physical contact with the third die.

16. A manufacturing method of a semiconductor package, comprising:
providing a first redistribution structure;
placing a first die on the first redistribution structure;
forming a first encapsulant on the first redistribution structure to laterally encapsulate the first die;
forming a second redistribution structure over the first die and the first encapsulant;
placing a second die on the second redistribution structure;
attaching a third die to the second redistribution structure through conductive connectors, wherein the third die is over the second die; and
encapsulating the second die and the conductive connectors by a second encapsulant such that the second encapsulant is in physical contact with the third die.

17. The method of claim 16, wherein at least a portion of each conductive connector is formed on the third die prior to the attachment of the third die to the second redistribution structure.

18. The method of claim 16, wherein prior to the attachment of the third die to the second redistribution structure, a first portion of each conductive connector is formed on the second redistribution structure, and a second portion of each conductive connector is formed on the third die.

19. The method of claim 18, wherein the first portion comprises a conductive post or a conductive ball, and the second portion comprises a conductive ball.

20. The method of claim 16, wherein encapsulating the second die and encapsulating the conductive connectors are performed simultaneously.
